(19) United States
(12) Patent Application Publication
(10) Pub. No.: US 2026/0173375 A1
(43) Pub. Date: Jun. 18, 2026

(54) THREE-DIMENSIONAL SEMICONDUCTOR DEVICES AND METHODS FOR FORMING THE SAME

(71) Applicant: Yangtze Memory Technologies Co., Ltd., Wuhan (CN)

(72) Inventors: Jianlan WEI, Wuhan (CN); Zongliang HUO, Wuhan (CN); Jing GAO, Wuhan (CN); Sizhe LI, Wuhan (CN); Xiaoming MAO, Wuhan (CN); Jiandong WANG, Wuhan (CN); Tingting ZHAO, Wuhan (CN); Zengpeng ZHANG, Wuhan (CN); Jiankang DU, Wuhan (CN)

(21) Appl. No.: 19/020,522

(22) Filed: Jan. 14, 2025

(30) Foreign Application Priority Data
Dec. 12, 2024 (CN) 202411836995.5

(51) Int. Cl. H10B 43/27; H10B 41/10; H10B 41/27; H10B 41/35; H10B 41/41; H10B 43/10; H10B 43/35; H10B 43/40

(52) U.S. Cl. CPC H10B 43/27; H10B 41/10; H10B 41/27; H10B 41/35; H10B 41/41; H10B 43/10; H10B 43/35; H10B 43/40

(57) ABSTRACT

The present disclosure relates to methods, devices, systems, and techniques for forming semiconductor devices. An example semiconductor device includes a first stack of conductive layers and isolating layers alternating with each other along a first direction and a second stack of dielectric layers and isolating layers alternating with each other along the first direction. The semiconductor device further includes an isolating wall between the first stack and the second stack along a second direction perpendicular to the first direction. The isolating wall includes isolating structures extending along the first direction and being aligned along a third direction perpendicular to the first direction and the second direction. The semiconductor device further includes contact structures extending through at least a part of the second stack along the first direction and connecting structures extending through the isolating wall along the second direction.

### CROSS-REFERENCE TO RELATED APPLICATIONS

This application claims priority to Chinese Patent Application No. 202411836995.5, filed on Dec. 12, 2024, which is hereby incorporated by reference in its entirety.

### TECHNICAL FIELD

The present disclosure relates to semiconductor devices and fabrication methods thereof.

### BACKGROUND

Semiconductor devices, e.g., memory devices, can have various structures to increase a density of memory cells and lines on a chip. For example, three-dimensional (3D) memory devices are attractive due to their capability to increase an array density by stacking more layers within a similar footprint. A 3D memory device normally includes a memory array of memory cells and peripheral circuits for facilitating operations of the memory array.

### SUMMARY

The present disclosure describes methods, devices, systems, and techniques forming semiconductor devices.

One aspect of the present disclosure features a semiconductor device. The semiconductor device includes a first stack of conductive layers and isolating layers alternating with each other along a first direction and a second stack of dielectric layers and isolating layers alternating with each other along the first direction. The semiconductor device further includes an isolating wall between the first stack and the second stack along a second direction perpendicular to the first direction. The isolating wall includes isolating structures extending along the first direction and being aligned along a third direction perpendicular to the first direction and the second direction. The semiconductor device further includes contact structures extending through at least a part of the second stack along the first direction and connecting structures extending through the isolating wall along the second direction. A connecting structure of the connecting structures connects a contact structure of the contact structures to a conductive layer of the conductive layers of the first stack, an isolating structure of the isolating structures extends through the connecting structure along the first direction, the conductive layer includes a first layer and a second layer surrounded by the first layer, the first layer and the second layer of the conductive layer are both in contact with the connecting structure, and the connecting structure and the first layer of the conductive layer include a same conductive material.

In some implementations, the connecting structure is connected to an end of the conductive layer along the second direction, and a size of the connecting structure along the first direction is different from a size of the end of the conductive layer along the first direction.

In some implementations, an end of the connecting structure is connected to the end of the conductive layer along the second direction, the end of the connecting structure is in contact with and is surrounded by a first liner layer and a second liner layer disposed at two opposite sides of the end of the connecting structure along the first direction, the end of the conductive layer is in contact with and between the first liner layer and the second liner layer along the first direction, and a size of the end of the connecting structure along the first direction is larger than the size of the end of the conductive layer along the first direction.

In some implementations, a first portion of the end of the conductive layer extends into the connecting structure along the second direction, a second portion of the end of the conductive layer is in contact with and between a first liner layer and a second liner layer disposed at two opposite sides of the end of the conductive layer along the first direction, and the size of the connecting structure along the first direction is larger than a size of the second portion of the end of the conductive layer along the first direction.

In some implementations, a body of the conductive layer is connected to the end of the conductive layer along the second direction, the body of the conductive layer is in contact with and between the first liner layer and the second liner layer along the first direction, and the size of the second portion of the end of the conductive layer along the first direction is smaller than a size of the body of the conductive layer along the first direction.

In some implementations, the isolating wall further includes inner structures extending along the first direction and being spaced along the third direction and outer layers extending along the third direction and being spaced along the first direction. The inner structures and the isolating structures alternate with each other along the third direction. The inner structures and the isolating structures extend through the outer layers along the first direction. The inner structures are surrounded by the outer layers.

In some implementations, an outer layer of the outer layers includes a first layer and a second layer, and the first layer of the outer layer and the second layer of the outer layer includes different materials.

In some implementations, an inner structure of the inner structures includes a dielectric layer and a filler material surrounded by the dielectric layer.

In some implementations, along the third direction, a first size of the connecting structure at a first location is smaller than a second size of the connecting structure at a second location. The first location is closer to a center of the isolating structure than the second location along the second direction.

In some implementations, the semiconductor device includes an array region and a connection region adjacent to the array region in the second direction, a first portion of the first stack is in the array region, a second portion of the first stack is in the connection region, the second stack is in the connection region, and the semiconductor device includes an array of channel structures in the array region.

In some implementations, the semiconductor device further includes a first semiconductor structure and a second semiconductor structure bonded together. The first semiconductor structure includes the first stack, the second stack, the isolating wall, the contact structures, and the connecting structure. The second semiconductor structure includes a peripheral circuit coupled to the first semiconductor structure and configured to control the semiconductor device.

Another aspect of the present disclosure features a semiconductor device. The semiconductor device includes a first stack of conductive layers and isolating layers alternating with each other along a first direction and a second stack of dielectric layers and isolating layers alternating with each other along the first direction. The semiconductor device further includes an isolating wall between the first stack and the second stack along a second direction perpendicular to the first direction. The isolating wall includes isolating structures extending along the first direction and being spaced along a third direction perpendicular to the first direction and the second direction. The semiconductor device further includes contact structures extending through at least a part of the second stack along the first direction and connecting structures extending through the isolating wall along the second direction. A connecting structure of the connecting structures connects a contact structure of the contact structures to an end of a conductive layer of the conductive layers of the first stack, an isolating structure of the isolating structures extends through the connecting structure along the first direction, and a size of the connecting structure along the first direction is different from a size of the end of the conductive layer along the first direction.

In some implementations, the connecting structure includes a first layer, the conductive layer includes a first layer and a second layer both in contact with the first layer of the connecting structure, and the first layer of the connecting structure and the first layer of the conductive layer include a same conductive material.

In some implementations, an end of the connecting structure is connected to the end of the conductive layer along the second direction, the end of the connecting structure is in contact with and between a first liner layer and a second liner layer disposed at two opposite sides of the end of the connecting structure along the first direction, the end of the conductive layer is contact with and between the first liner layer and the second liner layer along the first direction, and a size of the end of the connecting structure along the first direction is larger than the size of the end of the conductive layer along the first direction.

A further aspect of the present disclosure features a method of forming a semiconductor device. The method includes forming a first stack of conductive layers and isolating layers alternating with each other along a first direction and a second stack of dielectric layers and isolating layers alternating with each other along the first direction. The method further includes forming an isolating wall between the first stack and the second stack along a second direction perpendicular to the first direction. The isolating wall includes isolating structures extending along the first direction and being aligned along a third direction perpendicular to the first direction and the second direction. The method further includes forming contact structures extending through at least a part of the second stack along the first direction. The method further includes forming connecting structures extending through the isolating wall along the second direction. Forming the connecting structure includes forming a connecting structure of the connecting structures that connects a contact structure of the contact structures to a conductive layer of the conductive layers of the first stack. An isolating structure of the isolating structures extends through the connecting structure along the first direction, the conductive layer includes a first layer and a second layer surrounded by the first layer, the first layer and the second layer of the conductive layer are both in contact with the connecting structure, and the connecting structure and the first layer of the conductive layer include a same conductive material.

In some implementations, the method further includes forming a stack of dielectric layers and isolating layers alternating with each other along the first direction. The method further includes forming an array of channel holes, isolating holes, dummy channel holes, and gate line holes extending through the stack of dielectric layers and isolating layers along the first direction by a same etching process. The method further includes forming an array of channel structures in the array of channel holes, and isolating structures in the dummy channel holes. The method further includes forming inner holes by expanding and connecting the isolating holes. The inner holes and the isolating structures alternate with each other along the third direction. The method further includes forming tunnels between the isolating layers of the stack by removing a portion of the dielectric layers of the stack exposed by the inner holes. The tunnels extend along the third direction, and the inner holes and the isolating structures extend through the tunnels along the first direction.

In some implementations, forming the isolating wall includes forming outer layers of the isolating wall by depositing a first material on inner surfaces of the tunnels and filling a second material into the tunnels. Each outer layer includes a first layer including the first material and a second layer including the second material. Forming the isolating wall further includes forming inner structures of the isolating wall by removing a portion of the second material exposed by the inner holes and depositing at least a dielectric material into the inner holes. The method further includes forming a gate line space by expanding the gate line holes. The gate line space includes the expanded gate line holes connected with each other along the third direction.

In some implementations, forming the first stack of conductive layers and isolating layers and the second stack of dielectric layers and isolating layers includes removing the dielectric layers of the stack in an array region and the dielectric layers of the stack in a connection region between the gate line space and the isolating wall by an etching process. The etching process removes a portion of a first layer of an outer layer of the outer layers of the isolating wall and exposes a portion of a second layer of the outer layer. Forming the first stack of conductive layers and isolating layers and the second stack of dielectric layers and isolating layers further includes forming a dielectric spacer covering the exposed portion of the second layer of the outer layer. Forming the first stack of conductive layers and isolating layers and the second stack of dielectric layers and isolating layers further includes forming liner layers and the conductive layers between the isolating layers of the stack in the array region and the isolating layers of the stack in the connection region between the gate line space and the isolating wall to replace the removed dielectric layers. Forming the conductive layers includes forming the first layer of the conductive layer by depositing a first conductive material through the gate line space and forming the second layer of the conductive layer by depositing a second conductive material through the gate line space. The first stack includes the conductive layers and the isolating layers in the array region and the conductive layers and the isolating layers in the connection region between the gate line space and the isolating wall, the second stack includes a remaining portion of the dielectric layers of the stack and the isolating layers of the stack in the connection region, the dielectric spacer and the conductive layer are surrounded by one of the liner layers along the first direction, and a portion of the liner layer is in contact with and between the dielectric spacer and the conductive layer along the second direction.

In some implementations, the method further includes forming a gate line slit structure by filling the gate line space with a semiconductor material. The method further includes forming a contact hole in the connection region. The contact hole extends into the second stack along the first direction and reaches a dielectric layer of the dielectric layers of the second stack, the contact hole is aligned with the isolating structure along the second direction, and an outer layer of the outer layers of the isolating wall is in contact with and between the dielectric layer and the conductive layer along the second direction. The method further includes forming a first space in the dielectric layer by removing a portion of the dielectric layer between the contact hole and the outer layer to exposes the outer layer. The method further includes forming a second space by removing a portion of the first layer and the second layer of the outer layer to expose the dielectric spacer. The method further includes expanding the second space by removing the dielectric spacer to expose the liner layer. The method further includes expanding the second space by removing the liner layer to expose the conductive layer.

In some implementations, forming the connecting structure includes forming the connecting structure by depositing the first conductive material into the first space and the second space through the contact hole. Forming the contact structure includes forming a first layer of the contact structure by depositing the second conductive material on an inner surface of the contact hole and form a second layer of the contact structure by filling the contact hole with a dielectric material.

### BRIEF DESCRIPTION OF DRAWINGS

FIGS. 1A-1F illustrate an example semiconductor device.

FIGS. 2A-2D illustrate another example semiconductor device.

FIG. 3A(1)-3R illustrate an example process of manufacturing a semiconductor device.

FIG. 4A(1)-4P illustrate an example process of manufacturing another semiconductor device.

FIG. 5 illustrates a flow chart of an example process of manufacturing a semiconductor device.

FIG. 6 illustrates a block diagram of an example system.

Like reference numbers and designations in the various drawings indicate like elements. It is also to be understood that the various exemplary implementations shown in the figures are merely illustrative representations and are not necessarily drawn to scale.

### DETAILED DESCRIPTION

Due to a demand for cheaper memory devices with a higher density, a memory device (e.g., a 3D NAND flash memory) can be formed to have a large number of layers and a high aspect ratio. For example, the memory device can have multiple decks, and each deck can have multiple layers. Conductive layer filling and connections between contact structures and conductive layers are important steps in the manufacturing process of memory devices. The large number of layers and the high aspect ratio of such memory devices may bring challenges to the manufacturing process. For example, to improve the quality and reliability of the conductive layers, the conductive layer filling can be performed in separate processes (e.g., gate line loops in an array region and a connection region are carried out separately), and multiple sacrificial layers filling and removing steps can be involved in these processes, thereby increasing the fabrication complexity and reducing the processing window.

In some implementations, to improve the efficiency of the conductive layer filling process, an isolation wall is formed in the connection region to block the conductive layers from entering an undesired area. The conductive layer can be connected to a corresponding contact structure by a connecting structure that extends through the isolation wall. In some instances, a material (e.g., polysilicon) included in the isolation wall can be oxidized and thus can affect the electrical connectivity between the conductive layer and the contact structure. However, removing the oxidized portion (e.g., silicon oxide), for example, using hydrofluoric acid (HF), may damage existing tier oxide that is used for insulation. Therefore, fabrication methods that can solve the aforementioned issues without causing damage to existing structures in the memory devices are desirable.

In one or more implementations of the present disclosure, an example semiconductor device is provided. The semiconductor device includes a first stack of alternating conductive layers and isolating layers and a second stack of alternating dielectric layers and isolating layers. The semiconductor device further includes an isolating wall between the first stack and the second stack. The isolating wall includes an isolating structure extending along a vertical direction. The semiconductor device further includes a contact structure extending through at least a part of the second stack along the vertical direction and a connecting structure extending through the isolating wall along a horizontal direction. The connecting structure connects the contact structure to a conductive layer of the first stack. The isolating structure extends through the connecting structure along the vertical direction. The conductive layer includes a first layer and a second layer surrounded by the first layer. The first layer and the second layer of the conductive layer are both in contact with the connecting structure. The connecting structure and the first layer of the conductive layer include a same conductive material.

Implementations of the present disclosure can provide one or more of the following technical advantages and/or benefits. First, in the example semiconductor device described above, the sacrificial layer removal step can stop on the isolating wall. Second, the described techniques can reduce a number of fabrication loops to form conductive layers and contact structures and avoid multiple sacrificial layers filling and removing steps, thereby improving the product yield and reducing the fabrication costs. Third, the structure of the isolating wall is used to mitigate the polysilicon oxidation issue without causing damage to the existing tier oxide, and thus allows reliable connection structures to be formed.

The techniques can be applied to any semiconductor structures or devices that are configured to avoid electric leakage or breakdown, e.g., between conductive layers or components. The techniques can be applied to various types of semiconductor devices, volatile memory devices, such as DRAM memory devices, or non-volatile memory (NVM) devices, such as NAND flash memory, NOR flash memory, resistive random-access memory (RRAM), phase-change memory (PCM) such as phase-change random-access memory (PCRAM), spin-transfer torque (STT)-Magnetoresistive random-access memory (MRAM), among others. The techniques can also be applied to charge-trapping based memory devices, e.g., silicon-oxide-nitride-oxide-silicon (SONOS) memory devices, and floating-gate based memory devices. The techniques can be applied to three-dimensional (3D) memory devices. The techniques can be applied to various memory types, such as SLC (single-level cell) devices, MLC (multi-level cell) devices like 2-level cell devices, TLC (triple-level cell) devices, QLC (quad-level cell) devices, or PLC (penta-level cell) devices. Additionally or alternatively, the techniques can be applied to various types of devices and systems, such as secure digital (SD) cards, embedded multimedia cards (eMMC), or solid-state drives (SSDs), embedded systems, among others.

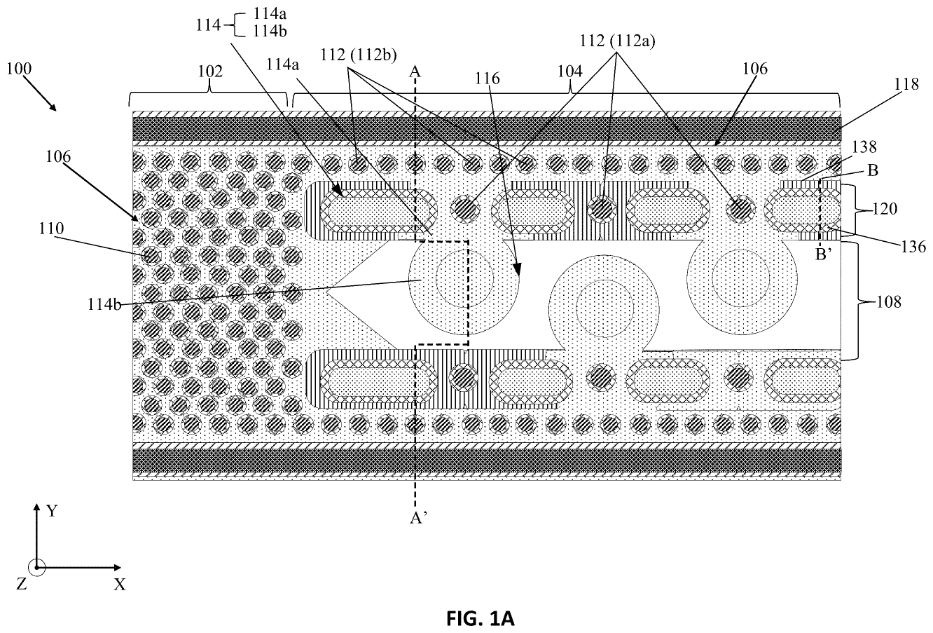

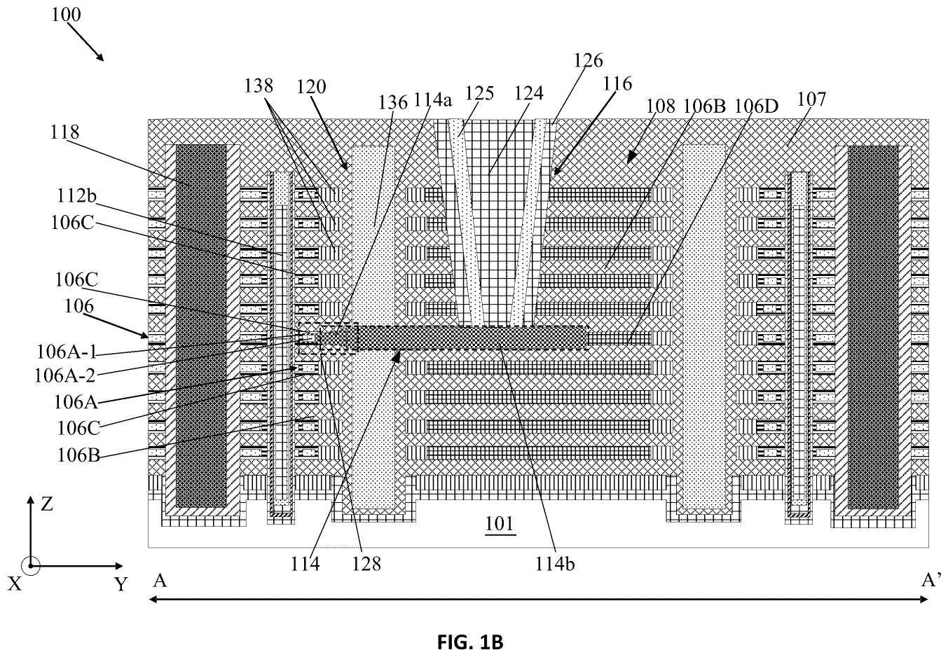

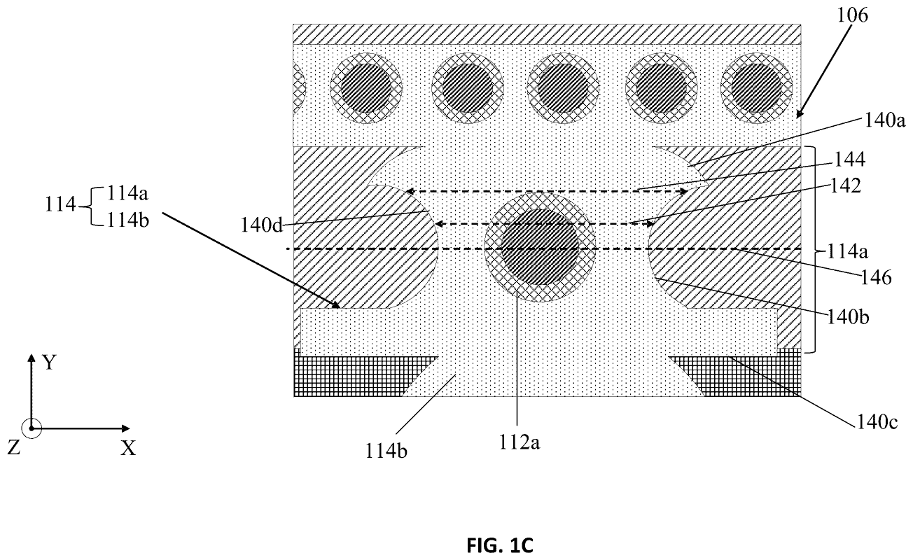

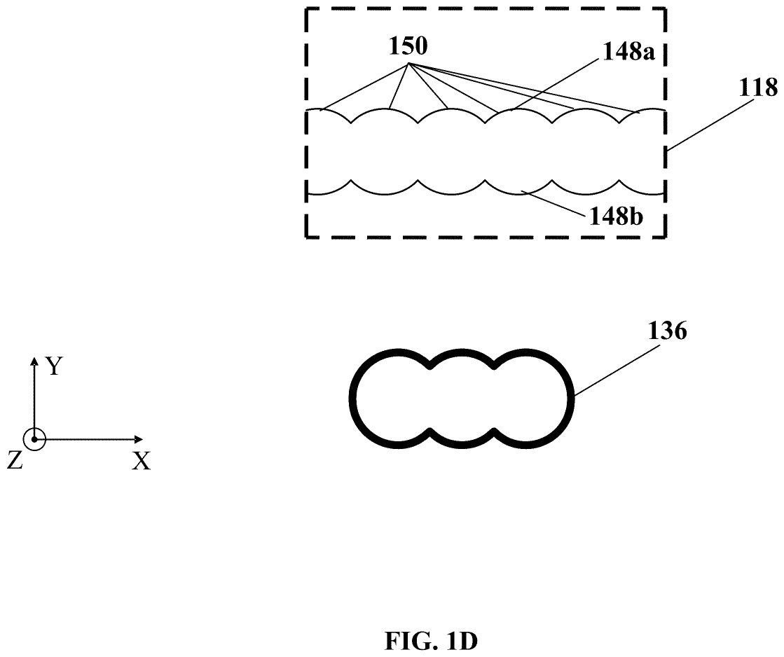

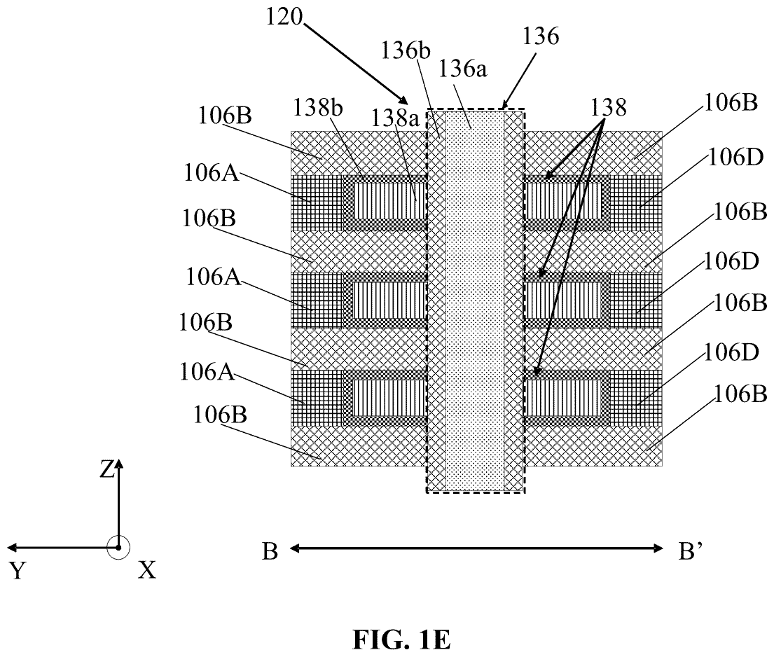

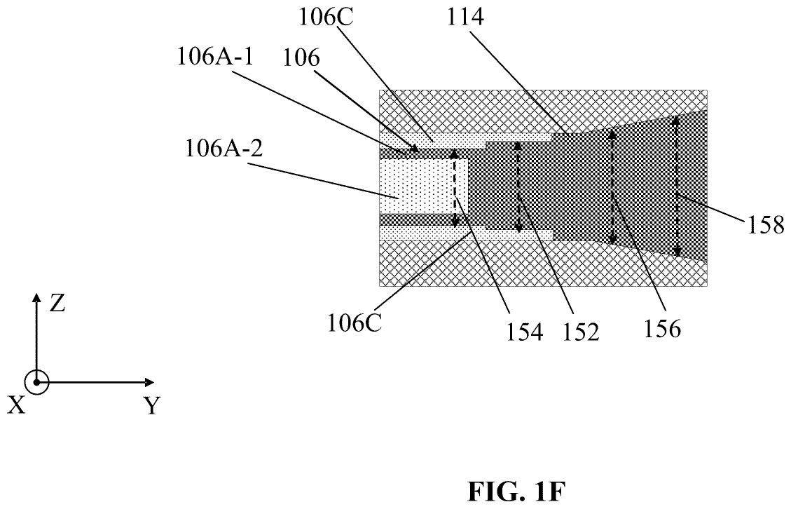

It is noted that X, Y, and Z axes (also referred to as X, Y, and Z directions) are included in FIGS. 1A-1F to further illustrate the spatial relationship of various components in a semiconductor device. A substrate of the semiconductor device can include two lateral surfaces extending laterally in the X-Y plane: a top surface on the front side of the substrate on which a component of the semiconductor device can be formed, and a bottom surface on the backside opposite to the front side of the substrate. The Z direction is perpendicular to both the X and Y directions. As used in the present disclosure, whether one component (e.g., a layer or a device) is “on,” “above,” or “below” another component (e.g., a layer or a device) of the semiconductor device is determined relative to the substrate of the semiconductor device in the Z direction (the vertical direction perpendicular to the X-Y plane, e.g., the thickness direction of the substrate) when the substrate is positioned in the lowest plane of the semiconductor device in the Z direction. The same notion for describing the spatial relationships is applied throughout the present disclosure.

FIG. 1A illustrates a top view of an example semiconductor device 100. In some implementations, the semiconductor device 100 can be a memory device, such as a three-dimensional (3D) NAND memory device. The semiconductor device 100 can include one or more array regions and one or more connection regions configured to provide conductive connections for the one or more array regions. In some implementations, as shown in FIG. 1A, the semiconductor device 100 includes an array region 102 and a connection region 104 adjacent to the array region 102 along a first horizontal direction (e.g., the X direction). It is understood that the example in FIG. 1A is for illustration purpose and is not intended to be construed in a limiting sense. In practice, any suitable arrangement of various regions in the semiconductor device 100 can be applied. In some instances, the semiconductor device 100 can have two connection regions 104 and an array region 102 arranged between the two connection regions 104 along the X direction. In some other instances, the semiconductor device 100 can have two array regions 102 and a connection region 104 between the two array regions 102 along the X direction.

The semiconductor device 100 includes a stack 106 of alternating conductive layers and isolating layers (e.g., conductive layers 106A and isolating layers 106B as shown in FIG. 1B). In some implementations, a part of the stack 106 can be in the array region 102, and another part of the stack 106 can be in the connection region 104. The semiconductor device 100 further includes a stack 108 of alternating dielectric layers and isolating layers (e.g., dielectric layers 106D and isolating layers 106B as shown in FIG. 1B). In some implementations, the stack 108 can be in the connection region 104. The stack 106 is connected to the stack 108.

The semiconductor device 100 can include one or more gate line slit structures 118. Each gate line slit structure 118 can extend in the X direction. The gate line slit structure 118 can extend into both the array region 102 and the connection region 104. In some implementations, the gate line slit structures 118 can divide an array region into multiple memory blocks. In some implementations, the gate line slit structure 118 can function as a common source contact for channel structures 110 in the array region 102.

The semiconductor device 100 can include isolating walls 120. The isolating walls 120 can be in the connection region 104. Each isolating wall 120 can separate the stack 106 (e.g., the portion of the stack 106 in the connection region 104) from the stack 108 along a second horizontal direction (e.g., the Y direction) perpendicular to the first horizontal direction (e.g., the X direction). The portion of the stack 106 in the connection region 104 can be between an adjacent gate line slit structure 118 and an adjacent isolating wall 120 along the Y direction. The isolating wall 120 can include inner structures 136 and outer layers 138. The inner structures 136 can extend along a vertical direction (e.g., the Z direction) perpendicular to the first horizontal direction (e.g., the X direction) and the second horizontal direction (e.g., the Y direction). The outer layers 138 can extend in a plane (e.g., the X-Y plane) perpendicular to the Z direction. The inner structures 136 can be spaced along the X direction.

The semiconductor device 100 can include contact structures 116 and connecting structures 114 in the connection region 104. The connecting structures 114 can extend through the isolating wall 120 along the Y direction. In some implementations, one of the conductive layers 106A of the stack 106 is coupled to a control circuit through a corresponding connecting structure 114 and a corresponding contact structure 116. For example, each contact structure 116 can extend through at least a part of the stack 108 along the Z direction and is connected to a corresponding connecting structure of the connecting structures 114. The corresponding connecting structure 114 is further connected to a corresponding conductive layer 106A of the stack 106 in the connection region 104. As shown in FIG. 1A, each connecting structure 114 can include a portion 114a and a portion 114b. The portion 114a is between the stack 106 and the stack 108 in the connection region 104 along the Y direction and extends through the isolating wall 120 along the Y direction. The portion 114a is connected to the conductive layer 106A along the Y direction. The portion 114b is connected to the contact structure 116 along the Z direction (as shown in FIG. 1B). Details of the portion 114a of the connecting structure 114 will be described below with reference to FIG. 1C.

The semiconductor device 100 can include an array of channel structures 110 extending through the stack 106 in the array region 102. Each channel structure 110 can be used to form a string of memory cells coupled in serial along the vertical direction (e.g., the Z direction). In some implementations, the semiconductor device 100 can include isolating structure 112 for process variation control during fabrication and/or for additional mechanical support. In some instances, the isolating structures can also be referred to as dummy channel structures or dummy memory strings. The isolating structures 112 can include isolating structures 112a extending along the Z direction in the isolating walls 120 and isolating structures 112b extending through the stack 106 in the connection region 104 along the Z direction. In some implementations, the isolating structures or dummy channel structures 112 can be in one or more dummy regions or peripheral regions (not shown in FIG. 1A). The isolating structures 112a in an isolating wall 120 can be spaced along the X direction. For example, the isolating structures 112a in the same isolating wall 120 can be aligned along the X direction. As shown in FIG. 1A, the inner structures 136 and the isolating structures 112a in the same isolating wall 120 can alternate with each other along the X direction. The inner structures 136 and the isolating structures 112a in the same isolating wall 120 can be aligned along the X direction. In some implementations, an isolating structure 112a can extend through a corresponding connecting structure 114 along the Z direction. In some implementations, at least one of the isolating structures 112b is adjacent to a corresponding connecting structure 114 along the Y direction.

Each channel structure 110 can be in the shape of a cylinder or a pillar, and can include a high-K layer, a block layer surrounded by the high-K layer, a charge trapping layer (or a storage layer) surrounded by the block layer, a tunneling layer surrounded by the charge trapping layer, a channel layer surrounded by the tunneling layer, and a core filler layer surrounded by the channel layer, which extend through the conductive layers 106A and the isolating layers 106B of the stack 106 in the array region 102, and a channel contact formed above the core filler layer and being in contact with the channel layer. In some implementations, the channel layer can include silicon, such as amorphous silicon, polysilicon, or single crystalline silicon, the tunneling layer can include silicon oxide, silicon nitride, or any combination thereof, the blocking layer can include silicon oxide, silicon nitride, high-k dielectrics, or any combination thereof, and the charge trapping layer can include silicon nitride, silicon oxynitride, silicon, or any combination thereof. In some implementations, the tunneling layer, the charge trapping layer and the blocking layer, collectively referred to as a memory film, can include ONO dielectrics (silicon Oxide-silicon Nitride-silicon Oxide).

In some implementations, the isolating structure 112 and the channel structure 110 can have similar or the same structure and can be formed in the same manufacturing process. In some other implementations, the isolating structure 112 and the channel structure 110 can have different structures. For example, the isolating structure 112 can be a solid dielectric structure. In other words, the isolating structure 112 can be a continuous structure made of a dielectric material (e.g., silicon oxide).

FIG. 1B illustrates a cross-sectional view of the semiconductor device 100 along cut line AA′ of FIG. 1A. The semiconductor device 100 includes a substrate 101, the stack 106 of alternating conductive layers 106A and isolating layers 106B, and the stack 108 of alternating dielectric layers (also referred to as sacrificial layers) 106D and isolating layers 106B. Each isolating layer 106B can have a portion between two adjacent conductive layers 106A in the stack 106 and another portion between two adjacent dielectric layers 106D in the stack 108. The stack 106 and the stack 108 are provided over the substrate 101. The substrate 101 can be any suitable semiconductor substrate having any suitable semiconductor material, such as monocrystalline, polycrystalline or single crystalline semiconductor. For example, the substrate 101 can include silicon, silicon germanium (SiGe), germanium (Ge), gallium arsenide (GaAs), silicon on insulator (SOI), germanium on insulator (GOI), gallium nitride, silicon carbide, III-V compound, or any combinations thereof. In some implementations, the substrate 101 can be removed from the semiconductor device 100 in a later process of manufacturing the semiconductor device 100. The semiconductor device 100 can include a top layer 107 made of an isolating material (e.g., oxide).

The stack 106 can extend in the second horizontal direction (e.g., the Y direction) that is parallel to a top surface of the substrate 101 and perpendicular to the first horizontal direction (e.g., the X direction). The conductive layers 106A and the isolating layers 106B can alternate in the vertical direction (e.g., Z direction) perpendicular to the second horizontal direction (e.g., the Y direction). The conductive layers 106A can be the same or different from each other in thickness, for example, ranging from 10-500 nm, e.g., about 35 nm. The isolating layers 106B can also be the same or different from each other in thickness, for example, ranging from 10-500 nm, e.g., about 25 nm. It should be noted that the number of the conductive layers 106A and the isolating layers 106B shown in FIG. 1B is for illustration only and that any suitable number of the conductive layers 106A and the isolating layers 106B can be included in the stack 106. The conductive layers 106A can include any suitable conducting material, such as tungsten (W), cobalt (Co), copper (Cu), aluminum (Al), titanium nitride (TiN), polycrystalline silicon (polysilicon), doped silicon, silicides, or any combination thereof. The isolating layers 106B can include a dielectric material, such as silicon oxide, silicon nitride, silicon oxynitride, or any combination thereof. In some implementations, the isolating layers 106B can also include high-K dielectric materials, such as hafnium oxide, zirconium oxide, aluminum oxide, tantalum oxide, lanthanum oxide, or any combination thereof.

In some implementations, each of the conductive layers 106A can include a layer 106A-1 and a layer 106A-2 surrounded by the layer 106A-1. The layer 106A-1 and the layer 106A-2 can include different conductive materials. One of the conductive layers 106A is in contact with the connecting structure 114. For example, the layer 106A-1 and the layer 106A-2 of that conductive layer 106A are both in contact with the connecting structure 114 (e.g., the portion 114a). The connecting structure 114 and the conductive layer 106A connected to the connecting structure 114 are further described in detail with reference to FIG. 1F.

In some implementations, as illustrated in FIG. 1B, the stack 106 includes liner layers 106C. A liner layer 106C can cover part or all sides of a corresponding conductive layer 106A and be between the conductive layer 106A and two isolating layers 106B adjacent to the corresponding conductive layer 106A. The liner layer 106C can include a high-K dielectric material (e.g., Al₂O₃). In some examples, the conductive layer 106A includes a metallic material (e.g., W) and an adhesive material (e.g., TiN), and the adhesive material can be deposited between the metallic material and the high-K dielectric material. In some examples, the conductive layer 106A includes the metallic material (e.g., W), and the liner layer 106C includes the adhesive material (e.g., TiN) and the high-K dielectric material.

The stack 108 include dielectric layers 106D and isolating layers 106B alternating with each other along the vertical direction (e.g., Z direction). The stack 108 can be connected to the stack 106. The isolating layers 106B can extend into both the stack 106 and the stack 108 along the second horizontal direction (e.g., Y direction) in the connection region 104. A dielectric layer 106D in the stack 108 can extend to and be in contact with a corresponding conductive layer 106A (or a liner layer 106C surrounding the corresponding conductive layer 106A) in the stack 106. To fabricate the stack 106 and the stack 108, a series of alternating dielectric layers 106D and isolating layers 106B can be first formed. Then, dielectric layers 106D in a region of the stack 106 can be etched away, e.g., through an opening formed in the position of the gate line slit structure 118, while dielectric layers 106D in the stack 108 remain unchanged. Then, the liner layers 106C and the conductive layers 106A can be formed in replace of the dielectric layers 106D in the region of the stack 106 to form the stack 106.

The gate line slit structure 118 can extend through the stack 106 along the vertical direction (e.g., the Z direction). In some implementations, as shown in FIG. 1B, the gate line slit structure 118 can extend from the top layer 107 into the substrate 101 along the Z direction. The isolating structures 112 (e.g., 112a and 112b) also can extend through the stack 106 along the vertical direction (e.g., the Z direction). In some implementations, as shown in FIG. 1B, the isolating structures 112 can extend into the substrate 101 along the Z direction. The contact structure 116 can extend through at least a part of the stack 108 (e.g., a set of dielectric layers 106D and isolating layers 106B of the stack 108) along the Z direction. As shown in FIG. 1B, the contact structure 116 can include a first layer 124 and a second layer 125. The first layer 124 and the second layer 125 can extend along the Z direction. The second layer 125 can be surrounding and in contact with the first layer 124. The first layer 124 can include a dielectric material (e.g., silicon oxide). The second layer 125 can include a conductive material. In some implementations, the contact structure 116 can be surrounded by a contact spacer 126, and the contact spacer 126 can include a dielectric material (e.g., silicon oxide).

The second layer 125 of the contact structure 116 can be coupled to a corresponding conductive layer of the conductive layers 106A of the stack 106 through a corresponding connecting structure of the connecting structures 114. For example, as shown in FIG. 1B, the second layer 125 of the contact structure 116 can be connected to the corresponding connecting structure 114 along the Z direction. The corresponding connecting structure 114 can be connected to the corresponding conductive layer 106A along the Y direction. The portion 114a of the connecting structure 114 is connected to the conductive layer 106A along the Y direction. The portion 114b is connected to the contact structure 116 along the Z direction. The portion 114b is between two adjacent isolating layers 106B of the stack 108 along the Z direction. The connecting structures 114 can include a conductive material. In some implementations, both the second layer 125 of the contact structure 116 and the connecting structure 114 can include a same conductive material (e.g., W or TiN). In some other implementations, the second layer 125 of the contact structure 116 and the connecting structure 114 can include different conductive materials. For example, the second layer 125 of the contact structure 116 can include W, and the connecting structure 114 can include TiN.

As shown in FIG. 1B, the outer layers 138 of the isolating wall 120 can be spaced along the Z direction. Adjacent outer layers 138 can be separated by the isolating layer 106B in the stack 106 and the isolating layer 106B in the stack 108 along the Z direction. The inner structures 136 of the isolating wall 120 can extend through the outer layers 138 along the Z direction. The isolating structures 112a (not shown in FIG. 1B) can also extend through the outer layers 138 along the Z direction. In some implementations, the inner structures 136 and the outer layer 138 of the isolating wall 120 can include a same dielectric material (e.g., silicon oxide). The isolating wall 120 is further described in detail with reference to FIG. 1E.

In some implementations, the semiconductor device 100 is a bonded chip that include a first semiconductor structure and a second semiconductor structure (not shown in FIGS. 1A-1B). The first semiconductor structure can be stacked over the second semiconductor structure (e.g., along the Z direction). The first and second semiconductor structures can be jointed at a bonding structure or a bonding layer (not shown) therebetween. In some implementations, the bonding structure is disposed between the first and second semiconductor structures as a result of hybrid bonding (also known as “metal/dielectric hybrid bonding”), which is a direct bonding technology (e.g., forming bonding between surfaces without using intermediate layers, such as solder or adhesives) and can obtain metal-metal bonding and dielectric-dielectric bonding simultaneously. The first semiconductor structure can include the stack 106, the stack 108, the isolating walls 120, the contact structures 116, the connecting structures 114, the channel structures 110, and the isolating structures 112. The second semiconductor structure can include peripheral circuits coupled to the first semiconductor structure. The peripheral circuits can be configured to control components (e.g., the conductive layers 106A and the channel structures 110 as described above) of the first semiconductor structure. In some implementations, the peripheral circuits include a plurality of transistors (e.g., planar transistors and/or 3D transistors). Trench isolations (e.g., shallow trench isolations (STIs)) and doped regions (e.g., wells, sources, and drains of transistors) can be formed on or in the substrate as well. In some examples, the peripheral circuits are formed using complementary metal-oxide-semiconductor (CMOS) technology, and the second semiconductor structure can be formed on a semiconductor die referred to as a control die or a CMOS die.

FIG. 1C illustrate an enlarged top view of the connecting structure 114. The connecting structure 114 can include the portion 114a and the portion 114b connected along the Y direction. The portion 114a can have at least four sides 140a, 140b, 140c, and 140d. The side 140a is adjacent to the stack 106 in the connection region 104. The side 140c is in contact with the portion 114b. The sides 140b and 140d can be two concave surfaces that are curved inward. The sides 140b and 140d can be in contact with two adjacent inner structures 136 of the isolating wall 120 along the X direction. In other words, the sides 140b and 140d can form two back-to-back curved surfaces (e.g., half circles in the X-Y plane) disposed along the X direction. In some implementations, along the X direction, a first size of the portion 114a at a location 142 is smaller than a second size of the portion 114a at a location 144. The location 142 is closer to a center axis 146 of the isolating structure 112a than the location 144 along the Y direction. The isolating structure 112a extends through the connecting structure 114 along the Z direction. In some implementations, the center axis 146 of the isolating structure 112a can overlap with a center axis (e.g., extending along the X direction) of the isolating wall 120.

FIG. 1D illustrates an enlarged top view of the gate line slit structure 118 and the inner structure 136 of FIGS. 1A-1B. As shown in FIG. 1D, the gate line slit structure 118 can have at least two non-flat surfaces 148a and 148b opposite to each other (e.g., along the Y direction). Each of the two surfaces 148a and 148b includes a series of curved portions connected together. For example, the surface 148a includes curved portions 150 connected with one another along the X direction. In other words, the surfaces 148a and 148b are wave-like or caterpillar-like. In some implementations, a cross section of the gate line slit structure 118 has a shape of partial circles arranged in a line and connected together. The cross section of the gate line slit structure 118 is in the X-Y plane (e.g., perpendicular to the vertical direction). Similarly, the inner structure 136 can also have a series of curved surfaces connected together. For example, a cross section (e.g., in the X-Y plane) of the inner structure 136 has a shape of partial circles arranged in a line and connected together. In other words, the surfaces of the inner structure 136 are also wave-like or caterpillar-like.

FIG. 1E illustrates an enlarged cross-sectional view of an implementation of the isolating wall 120 along cut line BB′ of FIG. 1A. The outer layers 138 of the isolating wall 120 can be spaced along the Z direction. Adjacent outer layers 138 can be separated by the isolating layer 106B in the stack 106 and the isolating layer 106B in the stack 108 along the Z direction. The inner structures 136 of the isolating wall 120 can extend through the outer layers 138 along the Z direction. In some implementations, each inner structure 136 can include a filler material 136a and a dielectric layer 136b surrounding the filler material 136a. For example, the filler material 136a can be polysilicon or carbon, and the dielectric layer 136b can include a dielectric material such as silicon oxide. In some implementations, each outer layer 138 can include a filler material 138a and a dielectric layer 138b surrounding the filler material 138a. For example, the filler material 138a can be polysilicon, and the dielectric layer 138b can include a dielectric material such as silicon oxynitride. In some implementations, a size of the dielectric layer 138b along the Z direction can be in a range between 1 nm and 10 nm (e.g., about 5 nm). In some implementations, a size of the filler material 138 a along the Z direction can be in a range between 5 nm and 30 nm (e.g., about 15 nm), and a size of the outer layer 138 along the Y direction can be in a range between 100 nm and 800 nm (e.g., about 500 nm).

FIG. 1F is an enlarged side view of a region 128 of FIG. 1A, which illustrates an end of the conductive layer 106A connected to an end of the connecting structure 114. As shown in FIG. 1F, the conductive layer 106A can include the layer 106A-1 and the layer 106A-2 surrounded by the layer 106A-1. The layer 106A-1 can be between the layer 106A-2 and one of the liner layers 106C along the Z direction. The layer 106A-1 and the layer 106A-2 of that conductive layer 106A are both in contact with the end of the connecting structure 114 (e.g., the portion 114a) along the Y direction. In some implementations, the liner layers 106C can extend along the Y direction and cover a portion of the end of the connecting structure 114. For example, the end of the connecting structure 114 is in contact with and is surrounded by two liner layers 106C disposed at two opposite sides of the end of the connecting structure 114 along the Z direction. The end of the conductive layer 106A is also in contact with and between the two liner layers 106C along the Z direction. In the example of FIG. 1F, a size (e.g., 152) of the end of the connecting structure 114 along the Z direction is larger than a size (154) of the end of the conductive layer 106A along the Z direction. In other words, a portion of the liner layer 106C that is in contact with the connecting structure 114 can be thinner than another portion of the liner layer 106C that is in contact with the conductive layer 106A. In some implementations, along the Z direction, a portion (closer to the conductive layer 106A along the Y direction) of the connecting structure 114 can be thinner than another portion (farther away from the conductive layer 106A along the Y direction) of the connecting structure 114. For example, the connecting structure 114 can have two cross sections 156 and 158 perpendicular to the Y direction. The cross section 156 is closer to the end the conductive layer 106A than the cross section 158 along the Y direction. A size of the cross section 156 along the Z direction is smaller than a size of the cross section 158 along the Z direction. The layer 106A-1 and the layer 106A-2 of the conductive layer 106A can include different conductive materials. For example, the layer 106A-2 can include a metal (e.g., W), and the layer 106A-1 can include TiN. The connecting structure 114 can include a same conductive material such as W or TiN.

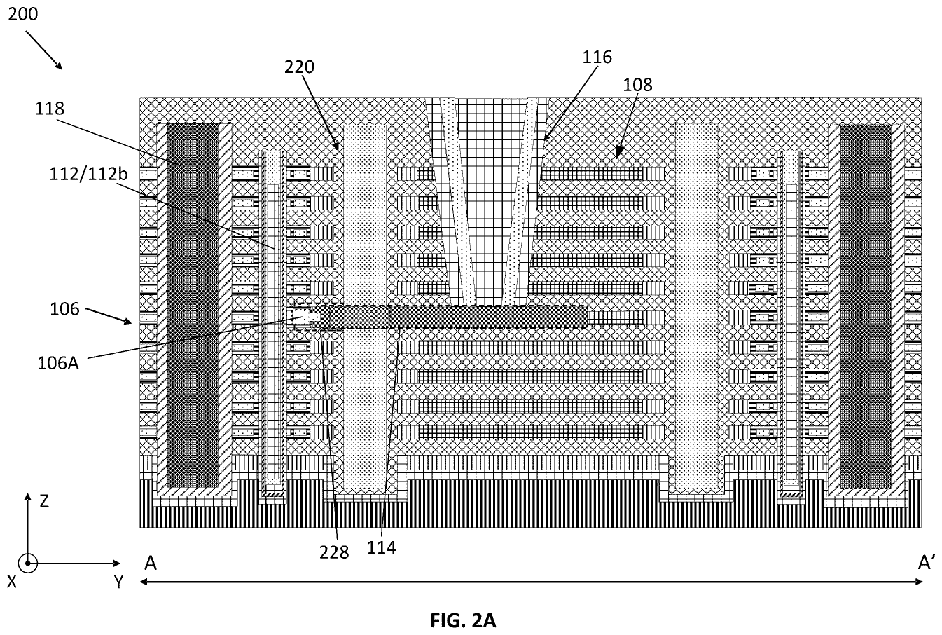

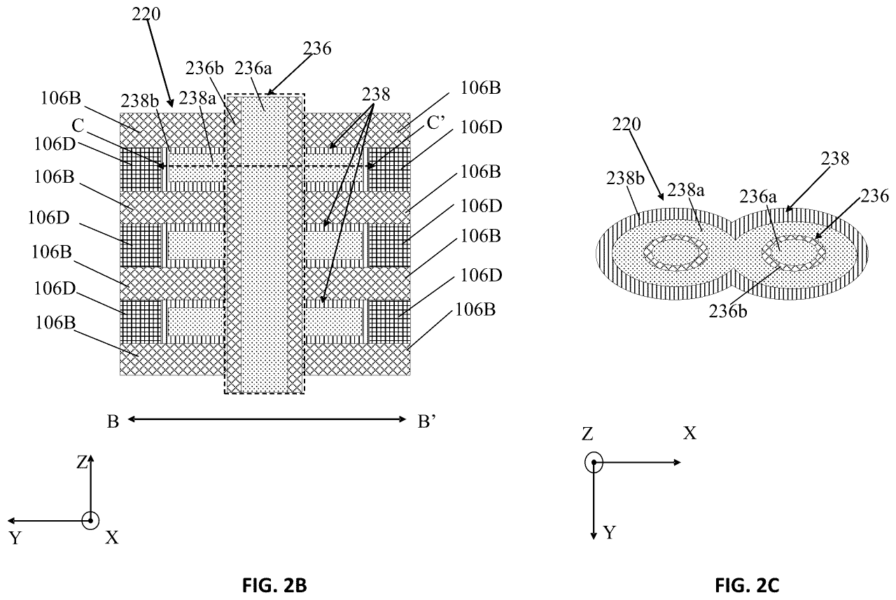

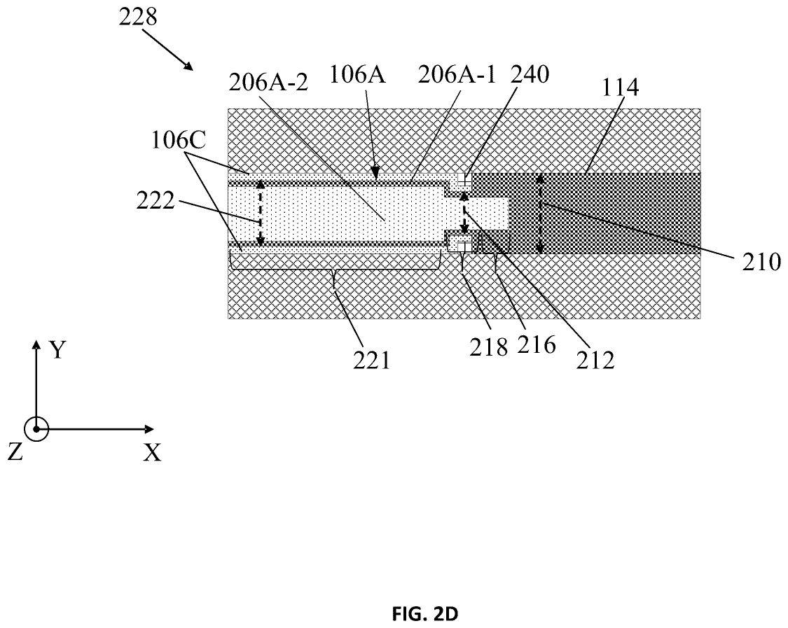

FIG. 2A illustrates a cross-sectional view of another example semiconductor device 200 along a cut line at the same location of the cut line AA′ of FIG. 1A. The semiconductor device 200 can be similar to the semiconductor device 100 of FIGS. 1A-1F and can also include the stack 106, the stack 108, the channel structures 110 (not shown in FIG. 2A), the isolating structures 112, the gate line slit structures 118, and the connecting structures 114, etc. As shown in FIG. 2A, the semiconductor device 200 can also include isolating walls 220. In some implementations, the isolating wall 220 of the semiconductor device 200 has a structure different from the isolating wall 120 of the semiconductor device 100 (e.g., as shown in FIG. 1E). FIG. 2B illustrates an enlarged cross-sectional view of the isolating wall 220 of the semiconductor device 200. The cross-sectional view is taken along a cut line at the same location of cut line BB′ of FIG. 1A. FIG. 2C illustrates an enlarged top view of the isolating wall 220 of the semiconductor device 200 along a cut line CC′ of FIG. 2B. As shown in FIG. 2B, similar to the isolating wall 120 of the semiconductor device 100, the isolating wall 220 of the semiconductor device 200 also include outer layer 238 and inner structures 236. The outer layers 238 of the isolating wall 220 can be spaced along the Z direction. Adjacent outer layers 238 can be separated by the isolating layer 106B in the stack 106 and the isolating layer 106B in the stack 108 along the Z direction. The inner structures 236 of the isolating wall 220 can extend through the outer layers 238 along the Z direction. In some implementations, as shown in FIGS. 2B-2C, each inner structure 236 can include a filler material 236a and a dielectric layer 236b surrounding the filler material 236a. For example, the filler material 236a can be polysilicon or carbon, and the dielectric layer 236b can include a dielectric material such as silicon oxide. In some implementations, each outer layer 238 can include a filler material 238a and a semiconductor layer 238b surrounding the filler material 238a. For example, the filler material 238a can be a high-K dielectric material, and the semiconductor layer 238b can include polysilicon. While FIG. 2C shows that a cross section of each inner structure 236 is in the shape of an ellipse, in practice, the cross section of the inner structure 236 can have any suitable shapes such as circles.

In some implementations, the connecting structure 114 of the semiconductor device 200 and the conductive layer 106A connected to the connecting structure 114 have structures different from those in the semiconductor device 100 (e.g., as shown in FIG. 1F). FIG. 2D is an enlarged side view of a region 228 of FIG. 2A, which illustrates an end of the conductive layer 106A of the semiconductor device 200 connected to an end of the connecting structure 114 of the semiconductor device 200. As shown in FIG. 2D, the conductive layer 106A can include a layer 206A-1 and a layer 206A-2 surrounded by the layer 206A-1. The layer 206A-1 can be between the layer 206A-2 and one of the liner layers 106C along the Z direction. The layer 206A-1 and the layer 206A-2 of that conductive layer 106A are both in contact with the end of the connecting structure 114 (e.g., the portion 114a) along the Y direction. As shown in FIG. 2D, the end of the conductive layer 106A can have a portion 216 and a portion 218 arranged along the X direction. The portion 216 extends into the connecting structure 114 along the X direction. The portion 218 is in contact with and between the two liner layers 106C disposed at two opposite sides of the conductive layer 106A along the Z direction. A dielectric spacer 240 can be surrounding the portion 218 and the two liner layers 106C. In other words, each of the liner layers 106C is between the portion 218 of the end of the conductive layer 106A and the dielectric spacer 240 along the Z direction. The dielectric spacer 240 can include a dielectric material such as silicon oxide. In some implementations, a size (e.g., 210) of the connecting structure 114 along the Z direction is larger than a size (e.g., 212) of the portion 218 of the end of the conductive layer 106A along the Z direction. A body 221 of the conductive layer 106A is connected to the end of the conductive layer along the X direction. The body 221 is in contact with and between the liner layers 106C along the Z direction. As shown in FIG. 2D, the end of the conductive layer 106A can be thinner than the body 221 of the conductive layer 106A. That is, the size (e.g., 212) of the portion 218 of the end of the conductive layer 106A along the Z direction is smaller than a size (e.g., 222) of the body 221 of the conductive layer 106A along the Z direction. The layer 206A-1 and the layer 206A-2 of the conductive layer 106A can include different conductive materials. For example, the layer 206A-2 can include a metal (e.g., W), and the layer 206A-1 can include TiN. The connecting structure 114 can include a same conductive material such as W or TiN.

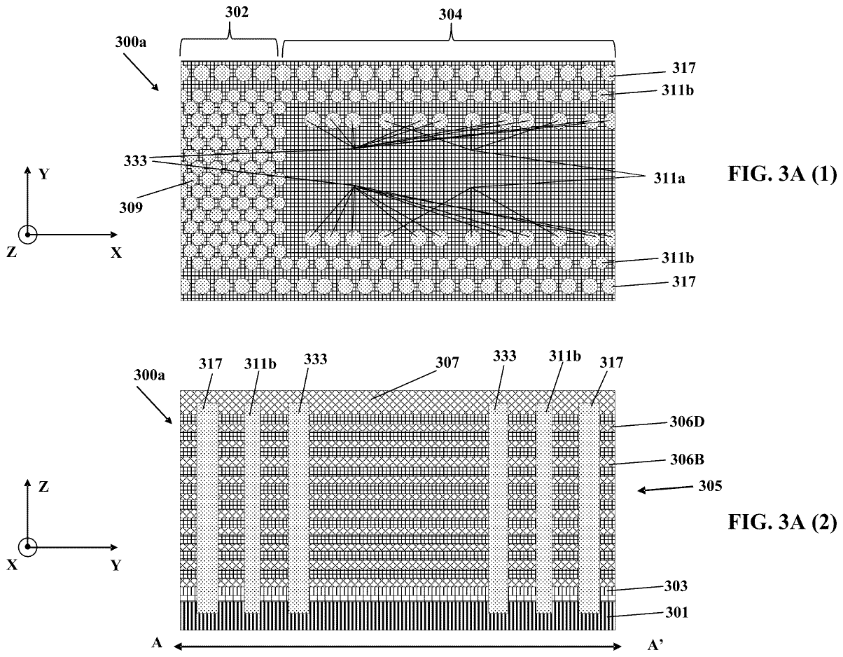

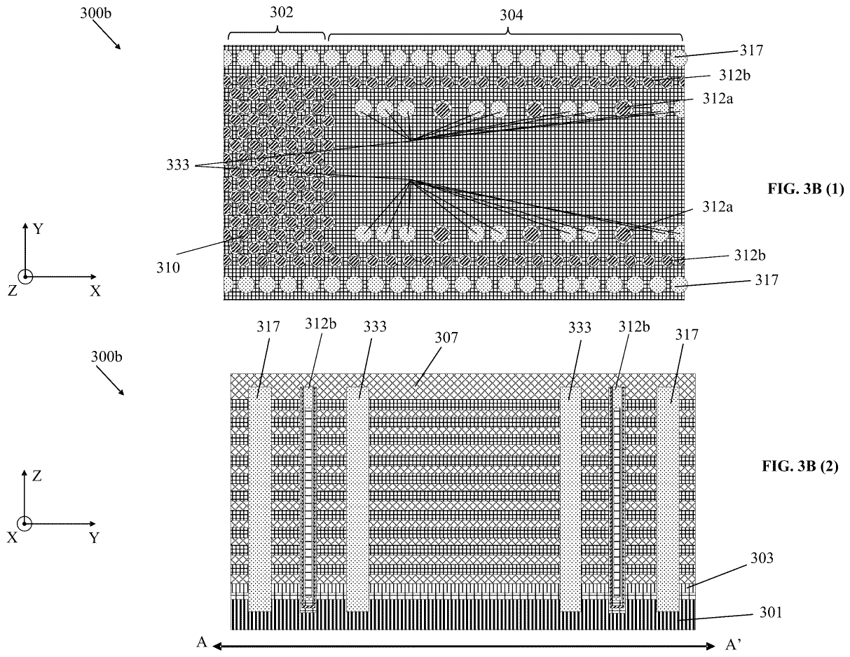

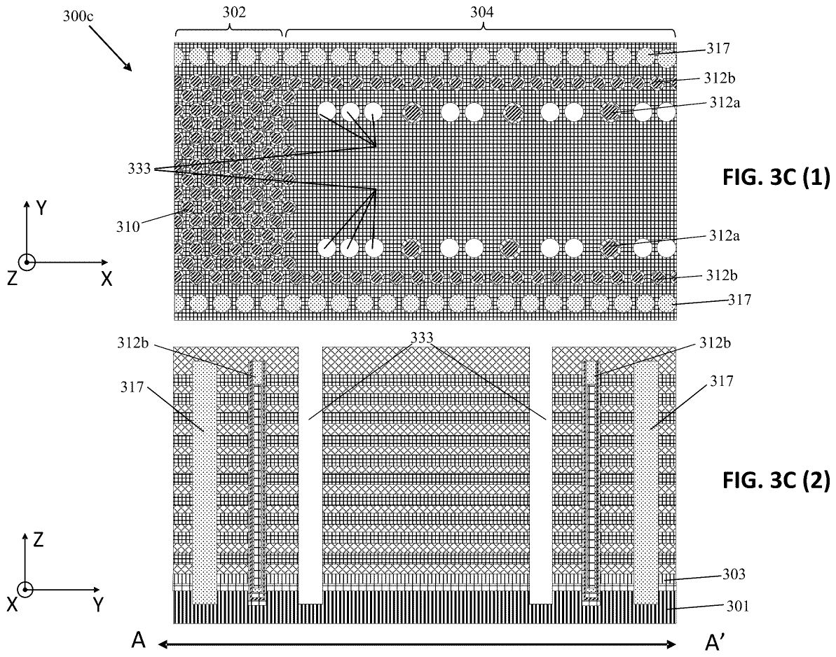

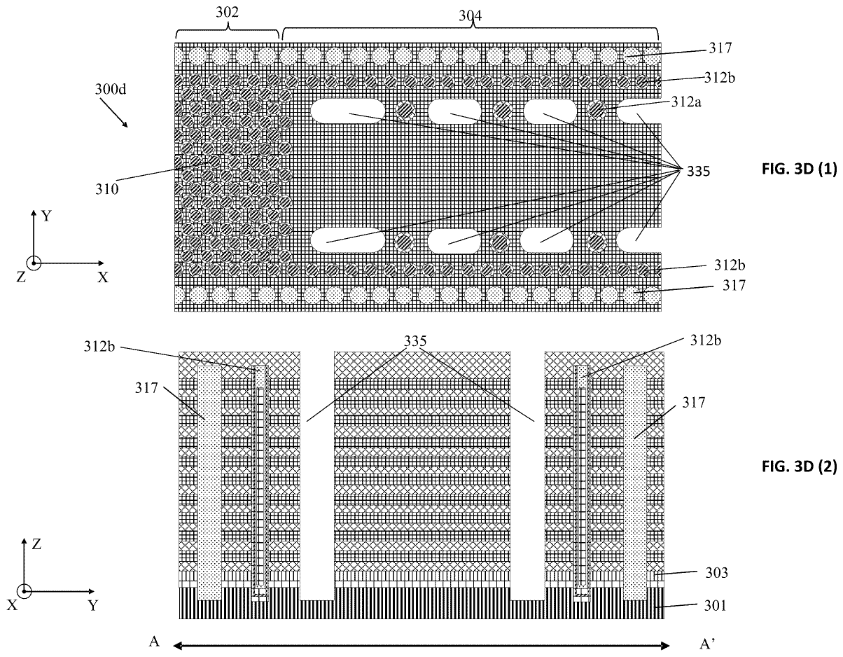

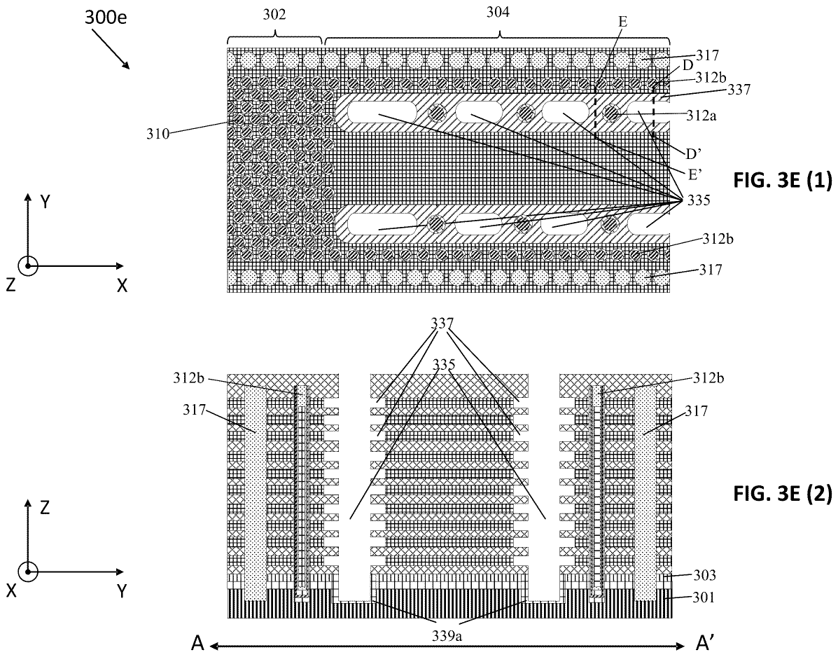

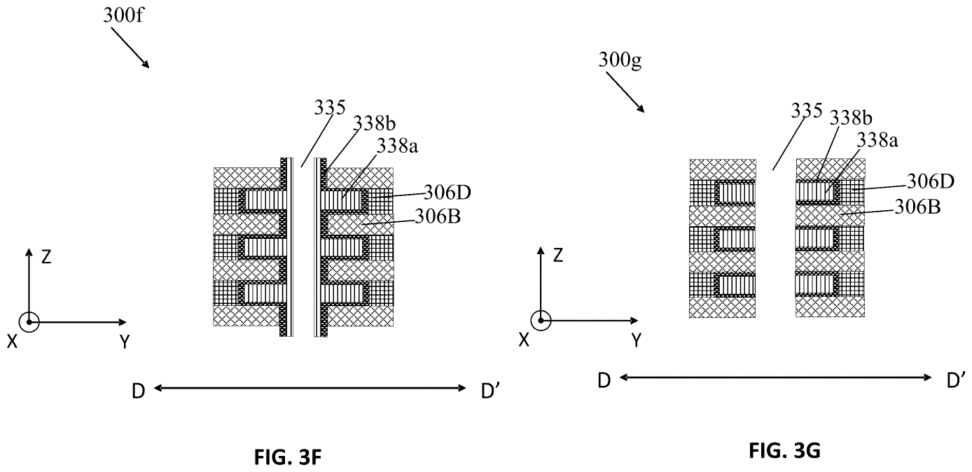

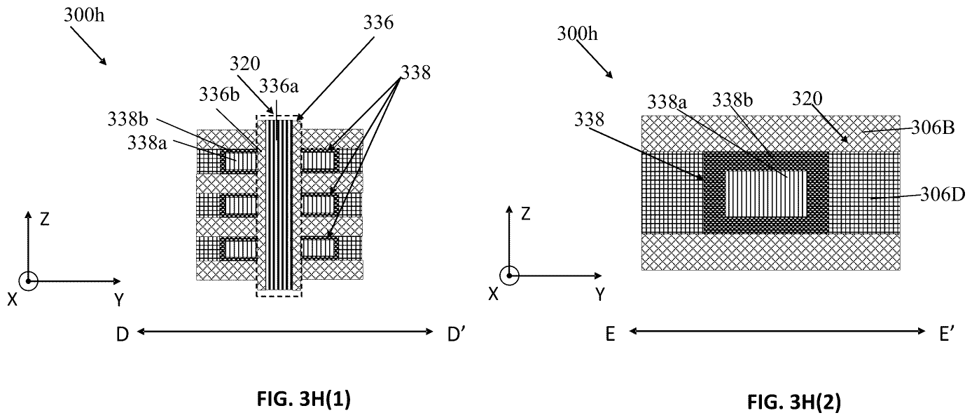

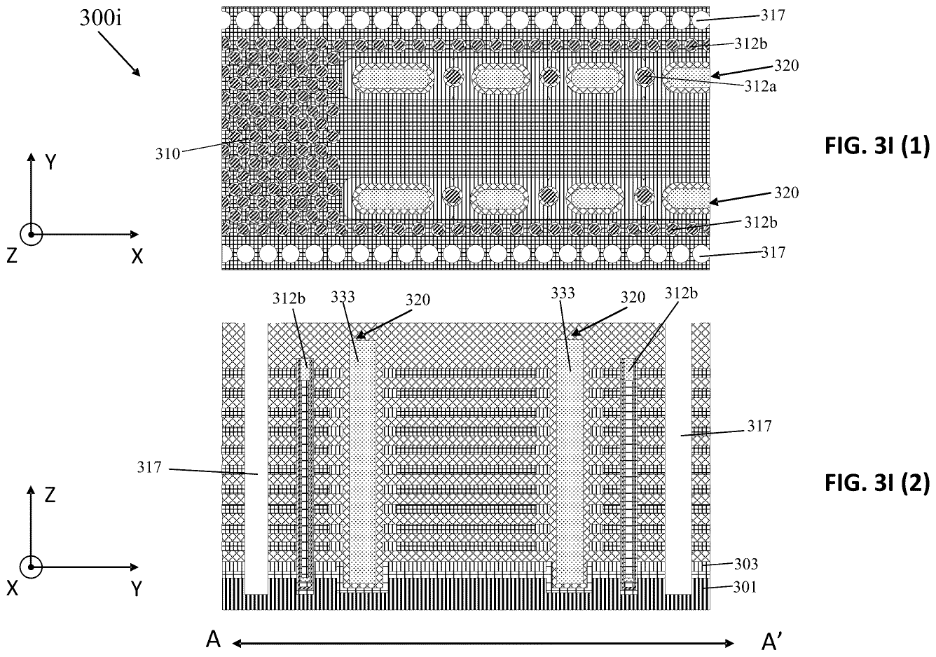

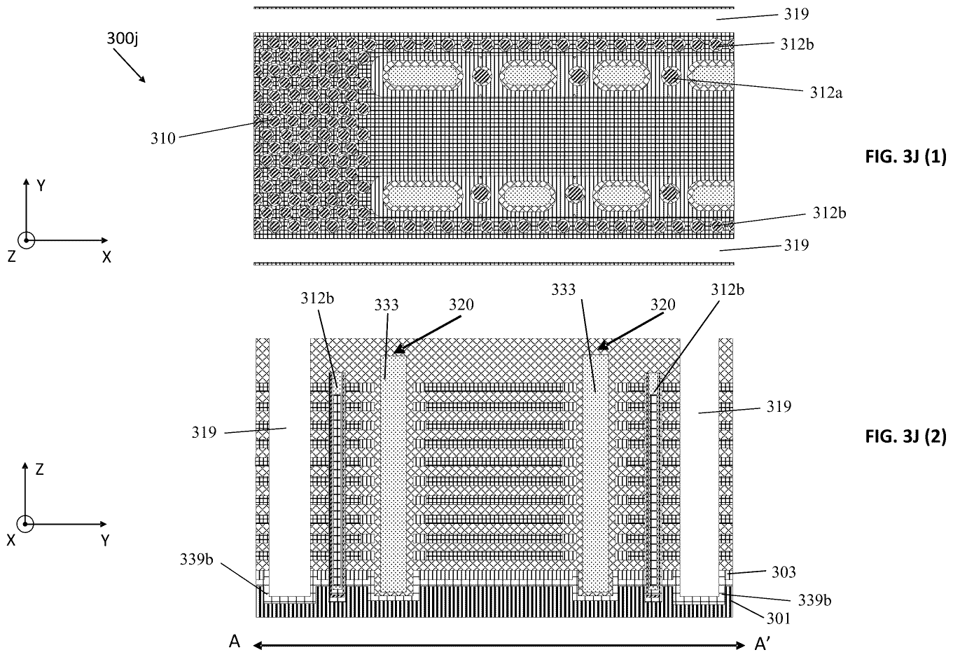

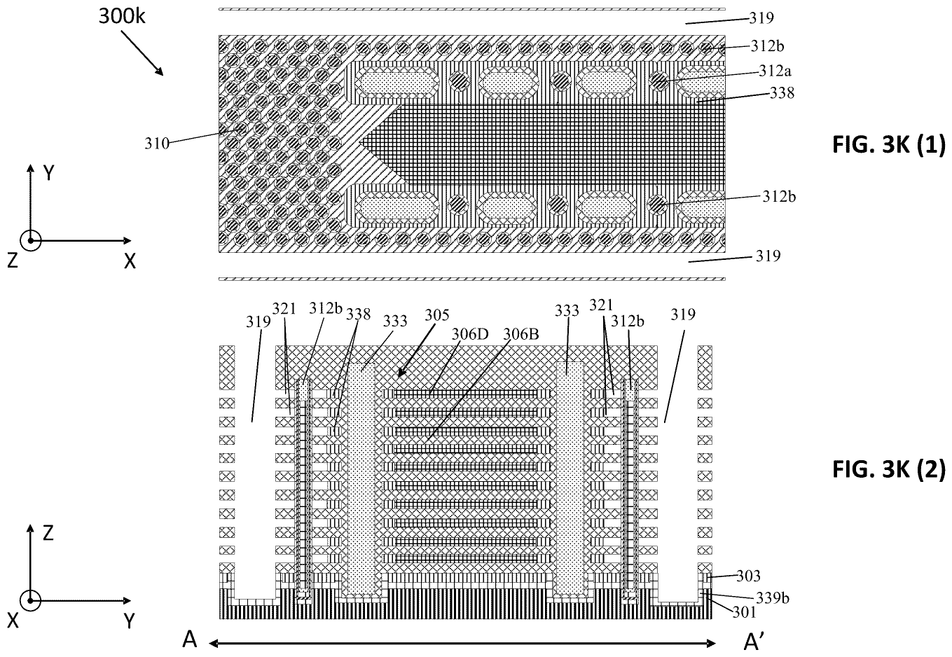

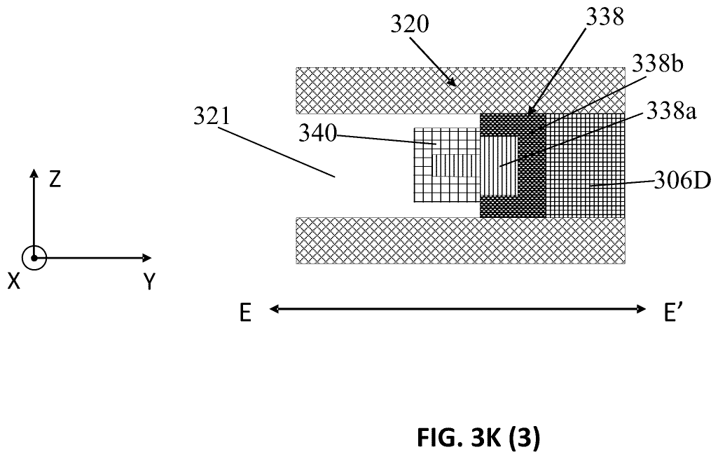

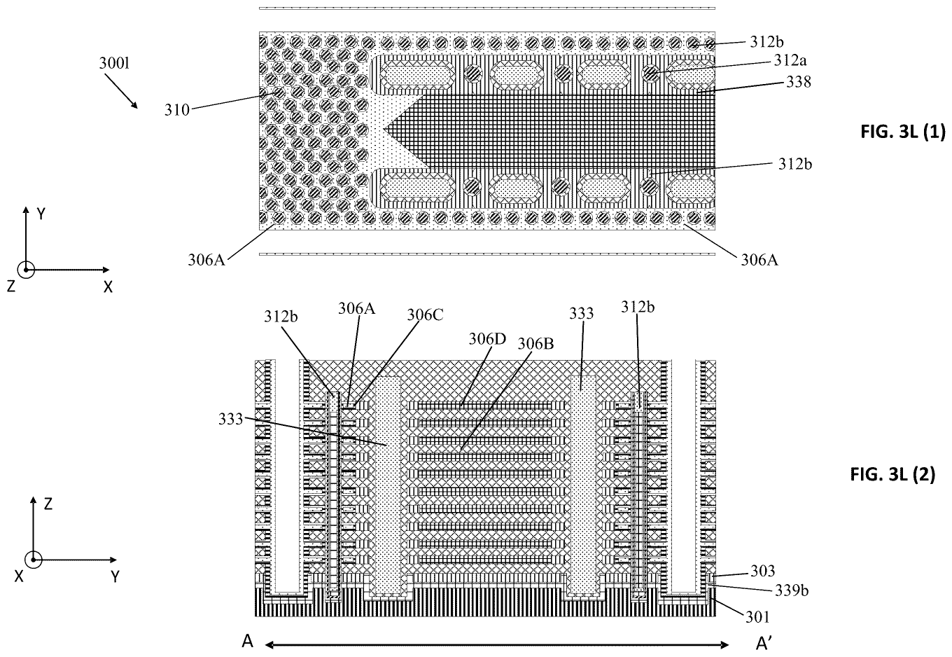

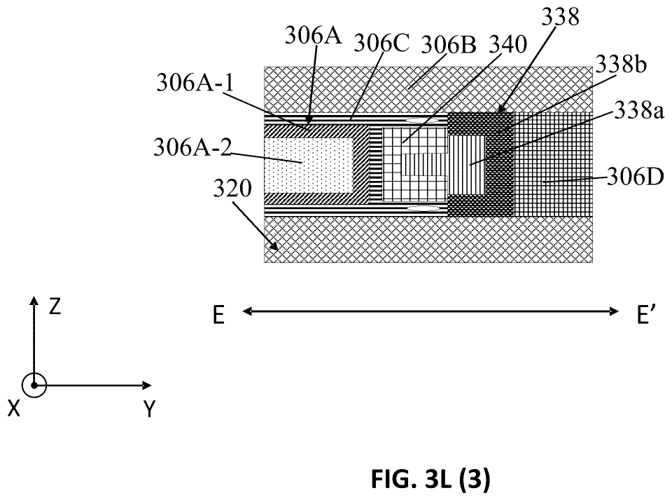

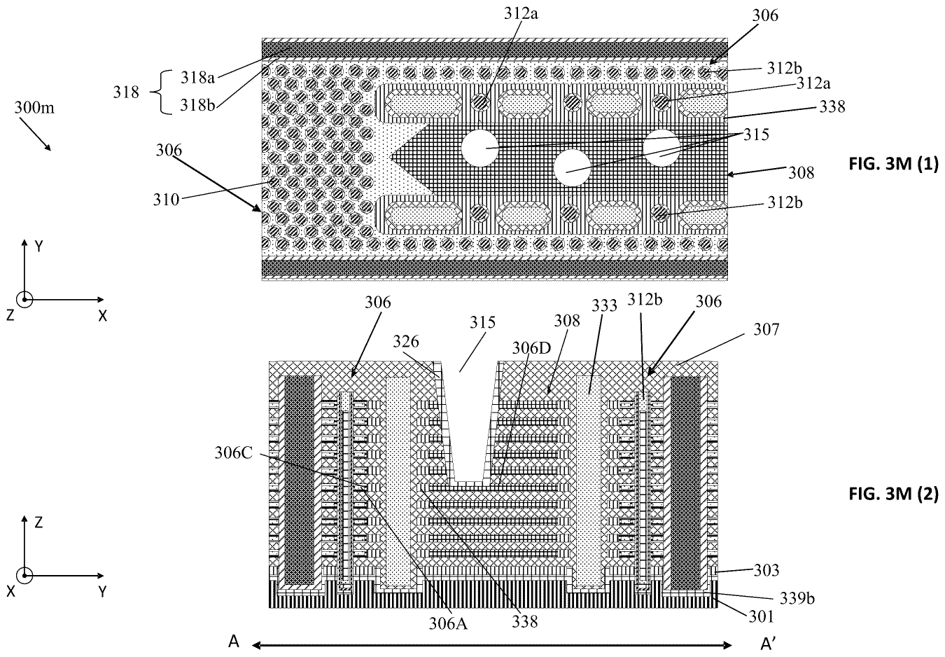

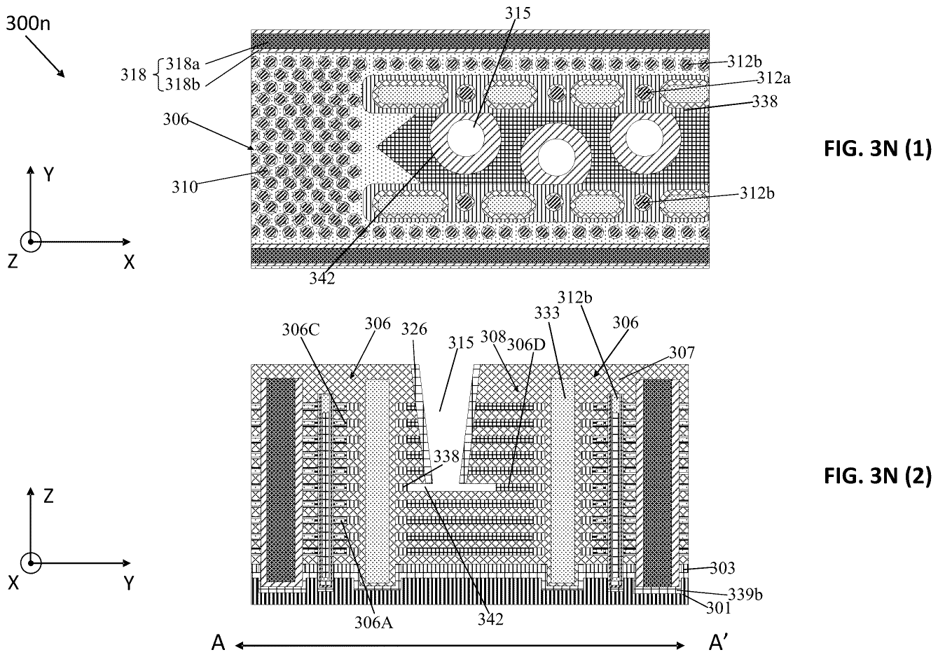

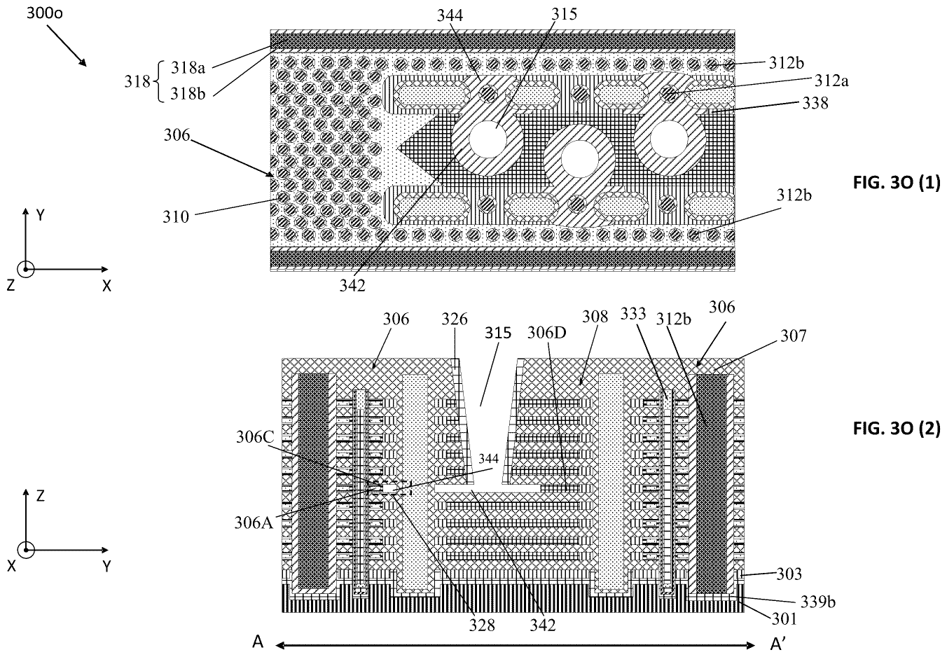

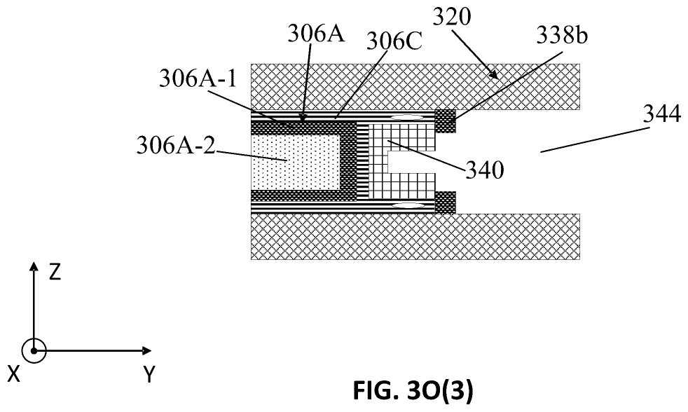

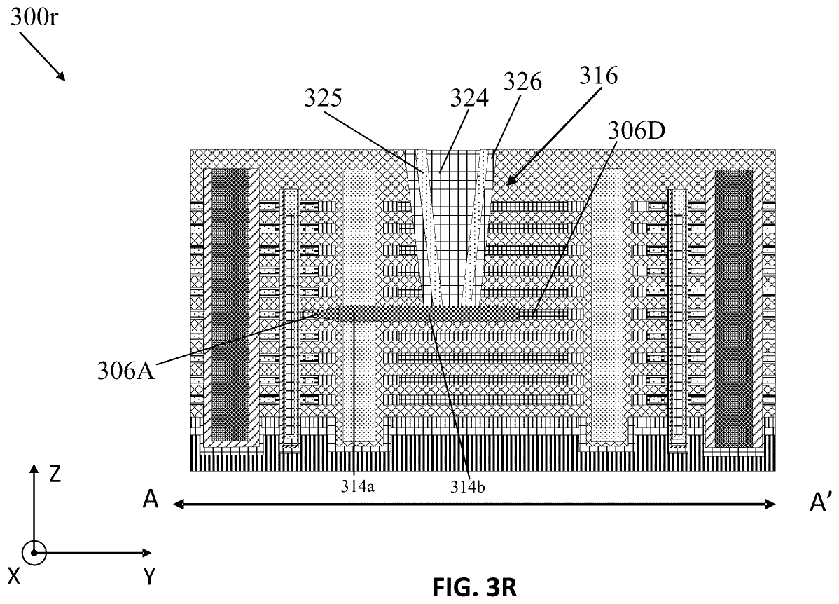

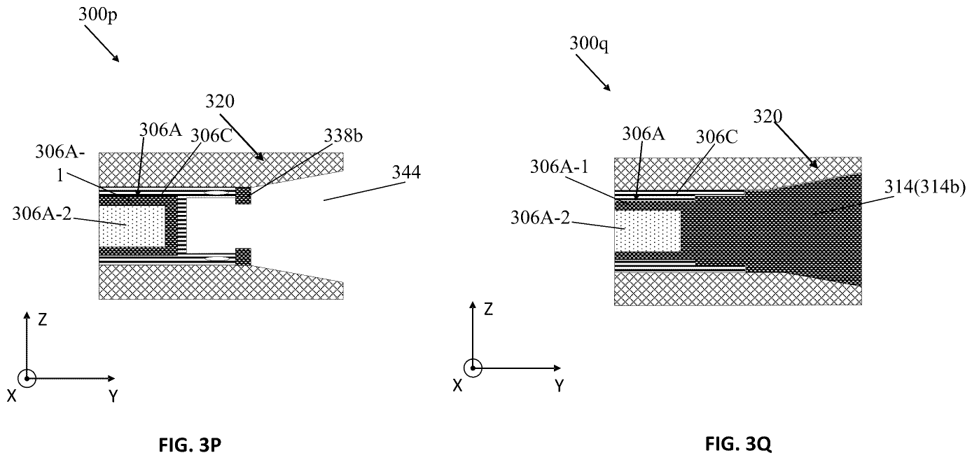

FIG. 3A(1)-3R illustrate an example process of fabricating a semiconductor device, such as the semiconductor device 100 as illustrated in FIGS. 1A-1F. FIG. 3A(1)-3R show top views and cross-sectional views of example semiconductor structures at various stages of the fabrication process.

As shown in FIG. 3A(1)-3A(2), a semiconductor structure 300a is formed. FIG. 3A(1) shows a top view of the semiconductor structure 300a. FIG. 3A(2) shows a cross sectional view of the semiconductor structure 300a along a cut line at the same location as the cut line AA′ of FIG. 1A. FIG. 3A(1) illustrates that the semiconductor structure 300a can have an array region 302 and a connection region 304 adjacent to the array region 302 (e.g., along the X direction). The array region 302 can be an example of the array region 102 of the semiconductor device 100 of FIG. 1A, and the connection region 304 can be an example of the connection region 104 of the semiconductor device 100. The semiconductor structure 300a includes a substrate 301 and a stack 305 of sacrificial layers 306D (also referred to as dielectric layers) and isolating layers 306B provided over the substrate 301. The stack 305 can extend across the array region 302 and the connection region 304. The sacrificial layers 306D and the isolating layers 306B can alternate with each other along the vertical direction (e.g., the Z direction). The substrate 301 and each of the sacrificial layers 306D and isolating layers 306B can extend in the X-Y plane. The semiconductor structure 300a further includes a semiconductor layer 303 between the stack 305 and the substrate 301 along the Z direction. The semiconductor layer 303 can be made of a suitable semiconductor material (e.g., polysilicon). The semiconductor structure 300a can be formed by, for example, depositing the stack 305 of sacrificial layers 306D and isolating layers 306B over the semiconductor layer 303. The isolating layers 306B can include dielectric material, such as silicon oxide, silicon nitride, silicon oxynitride, or any combination thereof. In some implementations, the sacrificial layers 306D can include a dielectric material different from the dielectric material of the isolating layers 306B. For example, the isolating layers 306B can include silicon oxide, and the sacrificial layers 306D can include silicon nitride.

The semiconductor structure 300a includes one or more groups of gate line holes 317. Each group of gate line holes 317 includes gate line holes in the array region 302 and gate line holes in the connection region 304. Each group of gate line holes 317 are arranged in a line extending along the X direction and are spaced from one another along the line. The semiconductor structure 300a includes an array of channel holes 309 in the array region 302. The semiconductor structure 300a includes one or more groups of isolating holes 333, one or more groups of first dummy channel holes 311a, and one or more groups of second dummy channel holes 311b in the connection region 304. Each group of second dummy channel holes 311b are arranged in a line extending along the X direction. A group of isolating holes 333 and a group of first dummy channel holes 311a are arranged in a line extending along the X direction. The group of isolating holes 333 can be separated by the group of first dummy channel holes 311a along the X direction. For example, as shown in FIG. 3A(1), one of the first dummy channel holes 311a is between two adjacent isolating holes of the group of isolating holes 333 along the X direction. Each group of second dummy channel holes 311b can be arranged between a group of gate line holes 317 and a group of first dummy channel holes 311a along the Y direction. The one or more groups of gate line holes 317, the array of channel holes 309, the one or more groups of isolating holes 333, the one or more groups of first dummy channel holes 311a, and the one or more groups of second dummy channel holes 311b can extend through the stack 305 of sacrificial layers 306D and isolating layers 306B along the Z direction. In some implementations, the one or more groups of gate line holes 317, the array of channel holes 309, the one or more groups of isolating holes 333, the one or more groups of first dummy channel holes 311a, and the one or more groups of second dummy channel holes 311b are formed by a same etching process.

The semiconductor structure 300a can be formed by filling a filler material (which is also referred to as a sacrificial material such as polysilicon or carbon) into the one or more groups of gate line holes 317, the array of channel holes 309, the one or more groups of isolating holes 333, the one or more groups of first dummy channel holes 311a, and the one or more groups of second dummy channel holes 311b. A dielectric layer 307 (e.g., silicon oxide) can be deposited on top of the semiconductor structure 300a to cover the one or more groups of gate line holes 317, the array of channel holes 309, the one or more groups of isolating holes 333, the one or more groups of first dummy channel holes 311a, and the one or more groups of second dummy channel holes 311b. A planarization process, such as chemical mechanical polishing (CMP), can be performed to remove the excess dielectric material on top of the semiconductor structure 300a.

As shown in FIG. 3B(1)-3B(2), a semiconductor structure 300b is formed by forming an array of channel structures 310 in the array of channel holes 309, first isolating structures 312a in the first dummy channel holes 311a, and second isolating structure 312b in the second dummy channel holes 311b. Openings can be formed to expose the filler material in the array of channel holes 309. The filler material in the array of channel holes 309 can be removed. The array of channel structures 310 can be formed by depositing a high-K layer, a memory film, a channel layer, and a core filler layer into each of the array of channel holes 309. The memory film can include a block layer, a charge trapping layer, and a tunneling layer. In some implementations, the channel layer can include silicon, such as amorphous silicon, polysilicon, or single crystalline silicon, the tunneling layer can include silicon oxide, silicon nitride, or any combination thereof, the blocking layer can include silicon oxide, silicon nitride, high-K dielectrics, or any combination thereof, and the charge trapping layer can include silicon nitride, silicon oxynitride, silicon, or any combination thereof. In some implementations, the first isolating structures 312a and the second isolating structure 312b can have similar structures as the channel structures 310. The first isolating structures 312a and the second isolating structure 312b can be referred to as dummy channel structures. In some implementations, the array of channel structures 310, the first isolating structures 312a, and the second isolating structure 312b can be formed by a same deposition process.

As shown in FIG. 3C(1)-3C(2), a semiconductor structure 300c is formed by forming openings in the dielectric layer 307 to expose the filler material in the isolating holes 333 and removing the filler material in the isolating holes 333. New isolating holes 333 can be formed which includes the isolating holes 333 (e.g., in the semiconductor structure 300b) and the openings on top of the isolating holes 333.

FIG. 3D(1)-3D(2) illustrate a semiconductor structure 300d including inner holes 335. The isolating holes 333 can be expanded, for example, by an etching process. Each inner hole 335 can be formed by connecting or merging adjacent isolating holes of the expanded isolating holes 333. As shown in FIG. 3D(1), the inner holes 335 and the first isolating structures 312a can alternate with each other along the X direction.

FIG. 3E(1)-3E(2) illustrate a semiconductor structure 300e including tunnels 337 between the isolating layers 306B of the stack 305. The tunnels 337 can be formed by an etching process, which removes a portion of the sacrificial layers 306D of the stack 305 exposed by the inner holes 335. The tunnels 337 can extend along the X direction. The inner holes 335 and the first isolating structures 312a can extend through the tunnels 337 along the Z direction. In some implementations, protection structures 339a (e.g., poly oxidation) can be formed on bottoms (which can be in contact with the substrate 301) of the inner holes 335 to protect the substrate 301.

FIG. 3F illustrates a semiconductor structure 300f including a filler layer 338a and a dielectric layer 338b. FIG. 3F illustrates a cross sectional view of the semiconductor structure 300f along a cut line DD′ of FIG. 3E(1). As shown in FIG. 3F, the dielectric layer 338b can be formed by depositing a dielectric material (e.g., silicon oxynitride) in the tunnels 337 and the inner holes 335. The dielectric layer 338b can be in contact with inner surfaces of the tunnels 337 and the inner holes 335. The filler layer 338a can be formed by further depositing a filler material (e.g., polysilicon) in the tunnels 337 and the inner holes 335. The filler layer 338a can fill the remaining space in the tunnels 337 and be surrounded by the dielectric layer 338b.

FIG. 3G illustrates a semiconductor structure 300g. As shown in FIG. 3G, the filler layer 338 a and the dielectric layer 338 b in the semiconductor structure 300g can be recessed (e.g., by one or more etching processes) to expose the isolating layers 306B in the inner holes 335.

FIG. 3H(1)-3H(2) illustrate a semiconductor structure 300h. FIG. 3H(1) illustrates a cross sectional view of the semiconductor structure 300h along the cut line DD′ of FIG. 3E(1). FIG. 3H(2) illustrates a cross sectional view of the semiconductor structure 300g along a cut line EE′ of FIG. 3E(1). The cut line DD′ extends through one of the inner holes 335, and the cut line EE′ does not extend through the inner holes 335. The semiconductor structure 300h includes one or more isolating walls 320. Each isolating wall 320 includes outer layers 338 and inner structures 336. The outer layers 338 can be similar to, or the same as, the outer layers 138 of FIG. 1E, and the inner structures 336 can be similar to, or the same as, the inner structures 136 of FIG. 1E. Each outer layer 338 can be formed by the filler layer 338a and the dielectric layer 338b of FIG. 3G. Each inner structure 336 can include a filler layer 336a and a dielectric layer 336b. The dielectric layer 336b is in contact with inner surfaces of the inner holes 335 and can be formed by depositing a dielectric material (e.g., silicon oxide) in the inner holes 335. The filler layer 336a can be formed by further depositing a filler material (e.g., carbon) in the inner holes 335.

As shown in FIG. 3I(1)-3I(2), a semiconductor structure 300i is formed by forming openings in the dielectric layer 307 to expose the filler material in the one or more groups of gate line holes 317 and removing the filler material in the one or more groups of gate line holes 317.

FIG. 3J(1)-3J(2) illustrate a semiconductor structure 300j including one or more gate line spaces 319. Each gate line space 319 can be formed by expanding one group of gate line holes 317 (e.g., by an etching process) and connecting or merging the group of expanded gate line holes 317. In some implementations, protection structures 339b (e.g., poly oxidation) can be formed on bottoms (which can be in contact with the substrate 301) of the one or more gate line spaces 319 to protect the substrate 301.

FIG. 3K(1)-3K(3) illustrate a semiconductor structure 300k including a space 321 formed by an etching process. For example, as shown in FIG. 3K(1)-3K(2), the etching process can include filling an etching solution into the gate line space 319. The space 321 is formed by removing the sacrificial layers 306D of the stack 305 in the array region 302 and portions of the sacrificial layers 306D of the stack 305 in the connection region 304 between each gate line space 319 and adjacent outer layers 338. A portion of each outer layer 338 can also be removed by the etching process. FIG. 3K(3) illustrate an enlarged cross sectional view of the outer layer 338 along the cut line EE′ of FIG. 3E(1). A portion of the dielectric layer 338b is removed by the etching process. A remaining portion of the dielectric layer 338b can be exposed in the space 321. In some implementations, an oxidation process (also referred to as a wet oxidation) is performed after the etching process. A portion of the filler layer 338a can be oxidized by the oxidation process, and the oxidized portion of the filler layer 338a (e.g., silicon oxide) can form a dielectric spacer 340. As shown in FIG. 3K(3), a remaining portion of the filler layer 338a is between the dielectric spacer 340 and the remaining portion of the dielectric layer 338b along the Y direction.

FIG. 3L(1)-3L(3) illustrate a semiconductor structure 300l including conductive layers 306A and liner layers 306C. The liner layers 306C and the conductive layers 306A can be formed, for example, by depositing (e.g., through the gate line spaces 319) a high-K dielectric material (e.g., Al2O3) and one or more conductive materials (e.g., TiN and W) into the space 321. In some implementations, as shown in FIG. 3L(2), the conductive layers 306A can be connected by excess conductive material deposited on inner surfaces of the gate line spaces 319. Each conductive layer 306A includes a portion between the isolating layers 306B in the array region 302. The conductive layer 306A further includes another portion in the space 321 in the connection region 304 (e.g., a portion between the gate line space 319 and adjacent outer layers 338 along the Y direction in the connection region 304). FIG. 3L(3) illustrate an enlarged cross sectional view (along the cut line EE′ of FIG. 3E(1)) of each conductive layer 306A and an adjacent outer layer 338. The conductive layer 306A includes a layer 306A-1 formed by a first conductive material (e.g., TiN) and a layer 306A-2 formed by a second conductive material (e.g., W). The layer 306A-2 is surrounded by the layer 306A-1. The conductive layer 306A and the dielectric spacer 340 are surrounded by one of the liner layers 306C formed by the high-K dielectric material along the Z direction. A portion of the liner layer 306C is between the conductive layer 306A and the dielectric spacer 340 along the Y direction. Another portion of the liner layer 306C is between the dielectric spacer 340 and the isolating layer 306B along the Z direction.

FIG. 3M(1)-3M(2) illustrate a semiconductor structure 300m including one or more gate line slit structures 318, a stack 306 of alternating conductive layers 306A and isolating layers 306B, and a stack 308 of alternating dielectric layers 306D and isolating layers 306B. The semiconductor structure 300m is formed by removing the excess conductive material deposited on inner surfaces of the gate line spaces 319, thereby isolating the conductive layers 306A from each other. Each gate line slit structure 318 can include a filling structure 318a and a dielectric layer 318b surrounding the filling structure. The filling structure 318a can include a filler material (e.g., polysilicon), and the dielectric layer 318b can include a dielectric material (e.g., silicon oxide). The gate line slit structures 318 can be formed by depositing the dielectric material and the filler material into the gate line spaces 319.

The stack 306 includes the conductive layers 306A and the liner layers 306C in the array region 302 and the connection region 304. The stack 306 further includes portions of the isolating layers 306B between the conductive layers 306A along the Z direction in the array region 302 and the connection region 304. The stack 308 includes remaining portions of the sacrificial layers or dielectric layers 306D in the connection region 304 and portions of the isolating layers 306B between the sacrificial layers 306D along the Z direction in the connection region 304. The stack 306 can be an example of the stack 106 of the semiconductor device 100 of FIGS. 1A-1B. The stack 308 can be an example of the stack 108 of the semiconductor device 100 of FIGS. 1A-1B.

The semiconductor structure 300m further includes contact holes 315 in the connection region 304. The contact holes 315 can be formed by one or more etching processes. Each contact hole 315 can extend from a top (e.g., a surface farther away from the substrate 301) of the semiconductor structure 300n through the dielectric layer 307 and to one of the sacrificial layers 306D of the stack 308. Each contact hole 315 can extend through at least a part of the stack 308 along the Z direction. For example, as shown in FIG. 3M(2), the contact hole 315 extends into the stack 308 along the Z direction and reaches one of the sacrificial layers 306D of the stack 308. In some implementations, a contact spacer 326 can be deposited on an inner surface of the contact hole 315. The contact spacer 326 can protect the sacrificial layers 306D exposed by the contact hole 315 from being affected by an etching process. In some implementations, each contact hole 315 is aligned with one of the first isolating structures 312a along the Y direction. As shown in FIG. 3M(2), one of the outer layers 338 is in contact with the sacrificial layer 306D and one of the conductive layers 306A along the Y direction. In some implementations, the outer layer 338 is connected to the conductive layer 306A through the liner layer 306C surrounding the conductive layer 306A.

FIG. 3N(1)-3N(2) illustrate a semiconductor structure 300n including a first space 342. The first space 342 can be formed in the sacrificial layer 306D of FIG. 3M(2) by removing (e.g., through an etching process) a portion of the sacrificial layer 306D that is in contact with the contact hole 315 (e.g., along the Z direction) to expose the outer layer 338. In some implementations, the etching process can etch off a portion of the outer layer 338 (e.g., a portion of the dielectric layer 338b of the outer layer 338 as shown in FIG. 3L(3)).

FIG. 3O(1)-3O(3) illustrate a semiconductor structure 300o including a second space 344. The second space 344 is connected to the first space 342 along the Y direction. The second space 344 can be formed by removing (e.g., through an etching process) the filler layer 338a of the outer layer 338 to expose the liner layer 306C. The first isolating structure 312a can extend through the second space 344 along the Z direction. FIG. 3O(3) illustrate an enlarged view of a region 328 of FIG. 3O(2). The enlarged view in FIG. 3O(3) is also a cross sectional view taken along the cut line EE′ of FIG. 3E(1). As shown in FIG. 3O(3), the filler layer 338a of the outer layer 338 (e.g., as shown in FIG. 3L(3)) has been removed. The dielectric layer 338b of the outer layer 338 may not be removed completely. In other words, the dielectric spacer 340 and a remaining portion of the dielectric layer 338b can be exposed in the second space 344.

FIG. 3P illustrates a semiconductor structure 300p formed by removing the dielectric spacer 340 (e.g., by an etching process). The second space 344 can be enlarged by the etching process.

FIG. 3Q illustrates a semiconductor structure 300q including a connecting structure 314. The connecting structure 314 can include a portion 314a (not shown in FIG. 3Q) in the first space 342 and a portion 314b in the second space 344. The semiconductor structure 300q can be formed by removing a portion of the liner layer 306C and the remaining portion of the dielectric layer 338b exposed in the space 344 (e.g., by an etching process). Then the connection structure 314 can be formed by depositing a conductive material (e.g., TiN or W) into the first space 342 and the second space 344 through the contact hole 315. The portion 314a of the connecting structure 314 can be similar to, or same as the portion 114a of FIG. 1C.

FIG. 3R illustrates a semiconductor structure 300r including contact structures 316. The semiconductor structure 300r is similar to, or same as the semiconductor device 100 of FIGS. 1A-1F. One of the contact structures 316 is connected to the portion 314b of the connecting structure 314 along the Z direction. Each contact structure 316 can include a first layer 324 and a second layer 325 surrounding and being in contact with the first layer 324. The second layer 325 can be surrounded by the contact spacer 326. The first layer 324 and the second layer 325 can extend along the Z direction. The first layer 324 can include a dielectric material (e.g., silicon oxide). The second layer 125 can include a conductive material. The second layer 325 of the contact structure 316 can be formed by depositing the conductive material on an inner surface of the contact hole 315. The first layer 324 of the contact structure 316 can be formed by filling the contact hole 315 with the dielectric material.

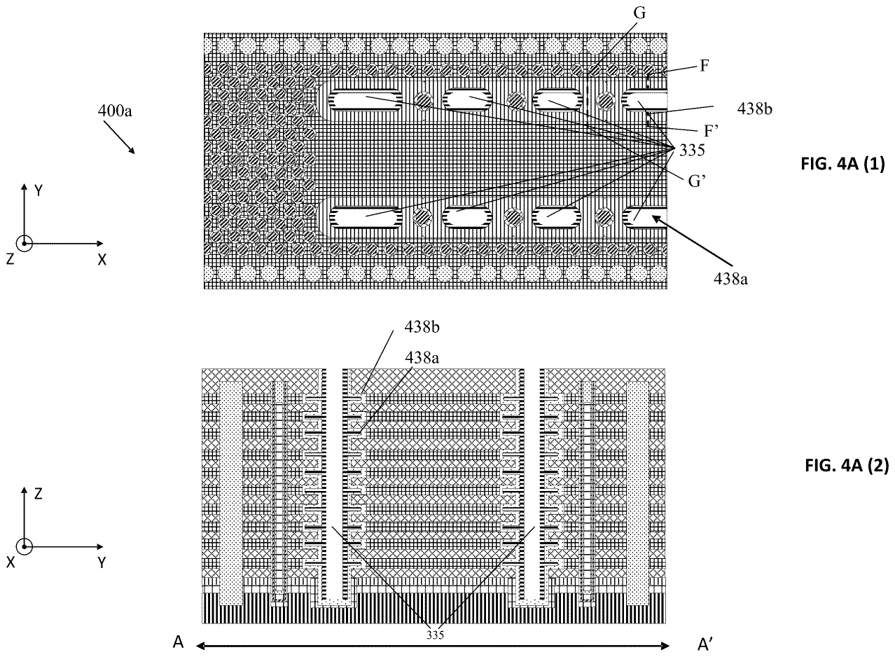

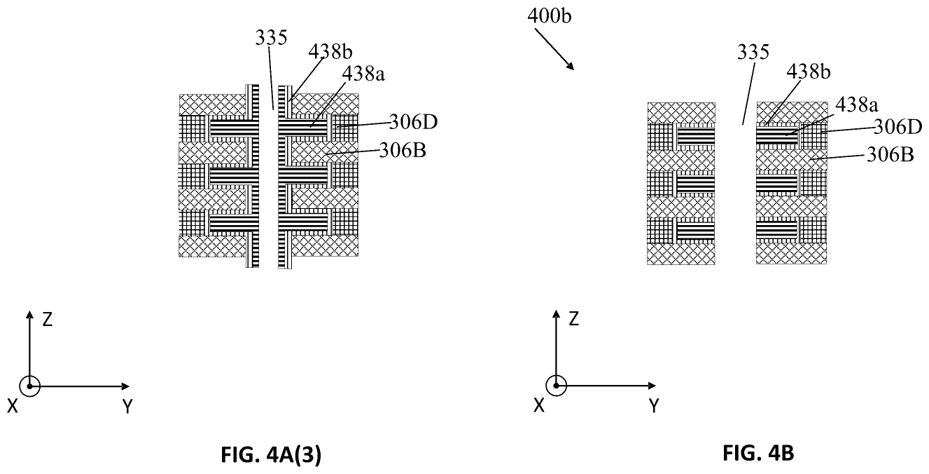

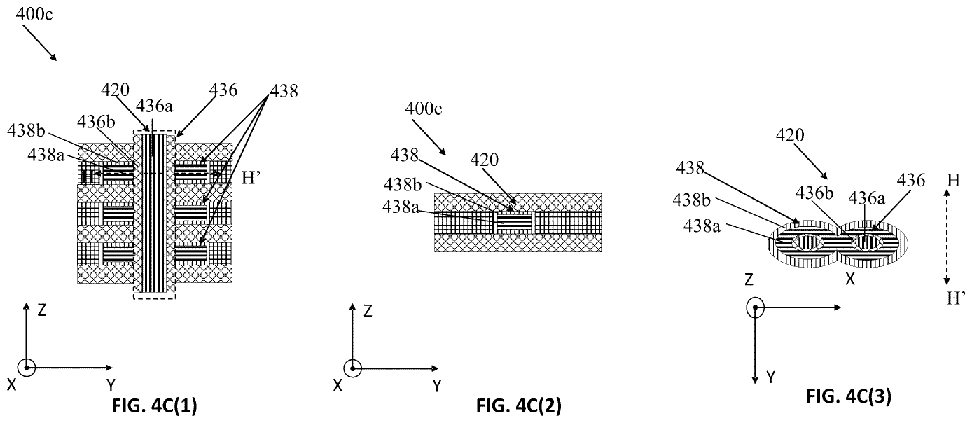

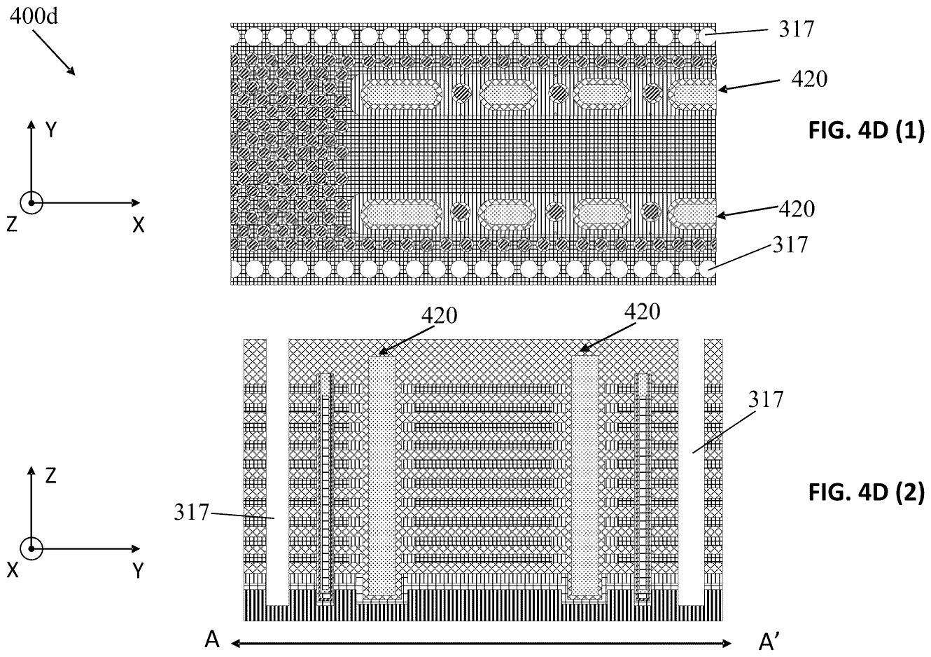

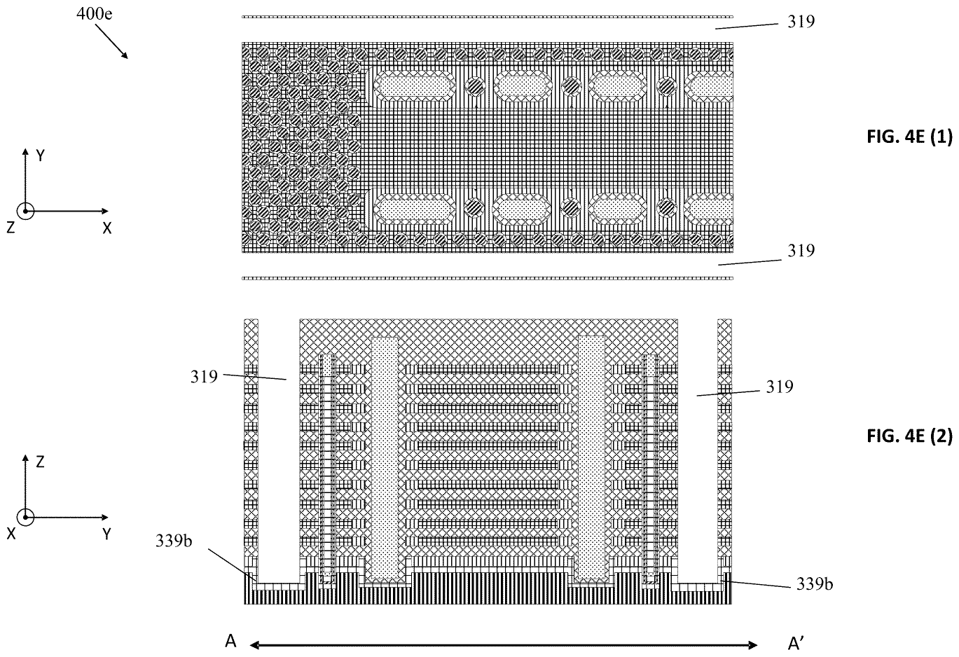

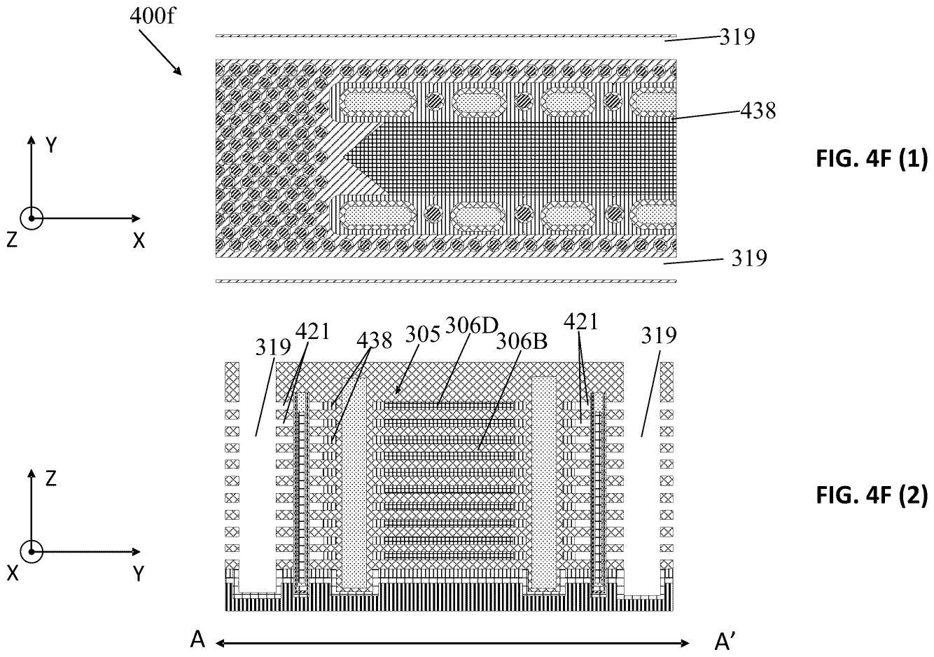

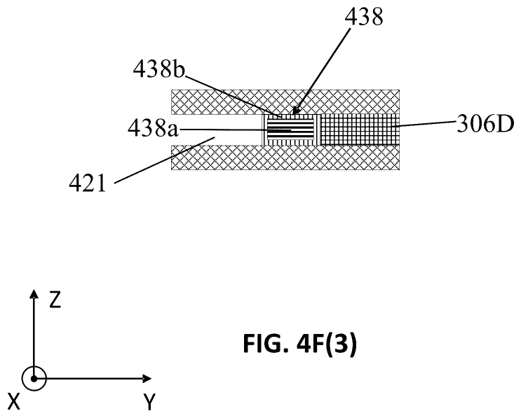

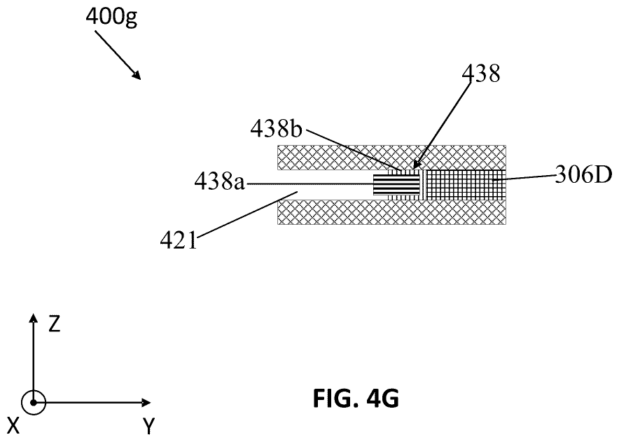

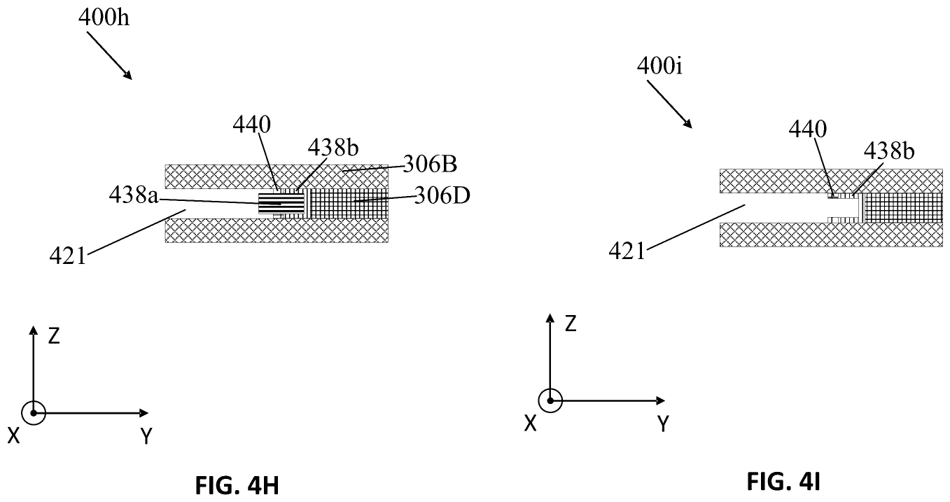

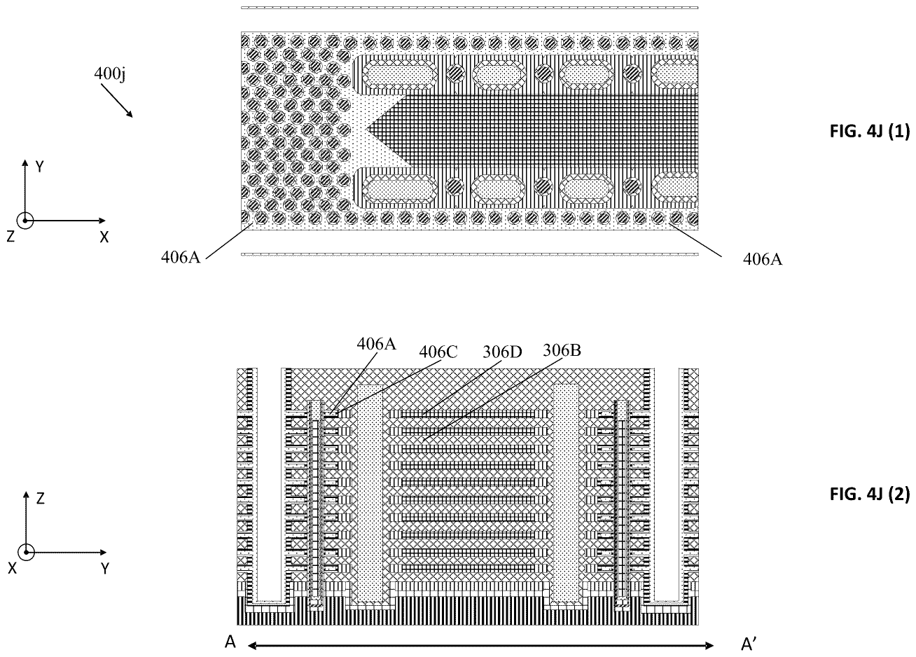

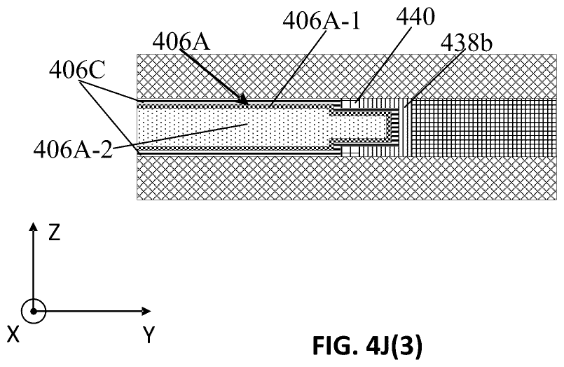

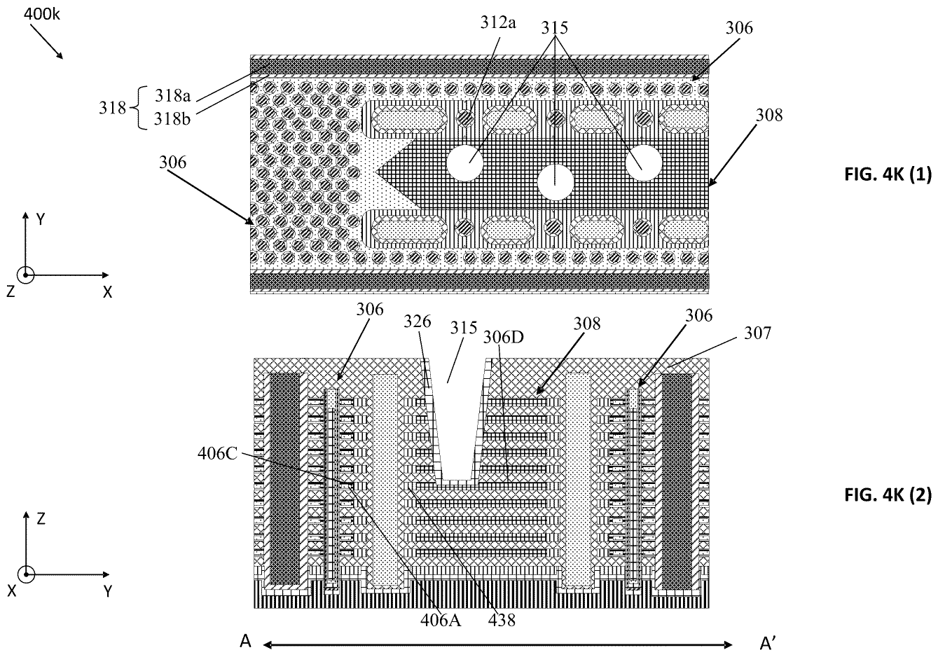

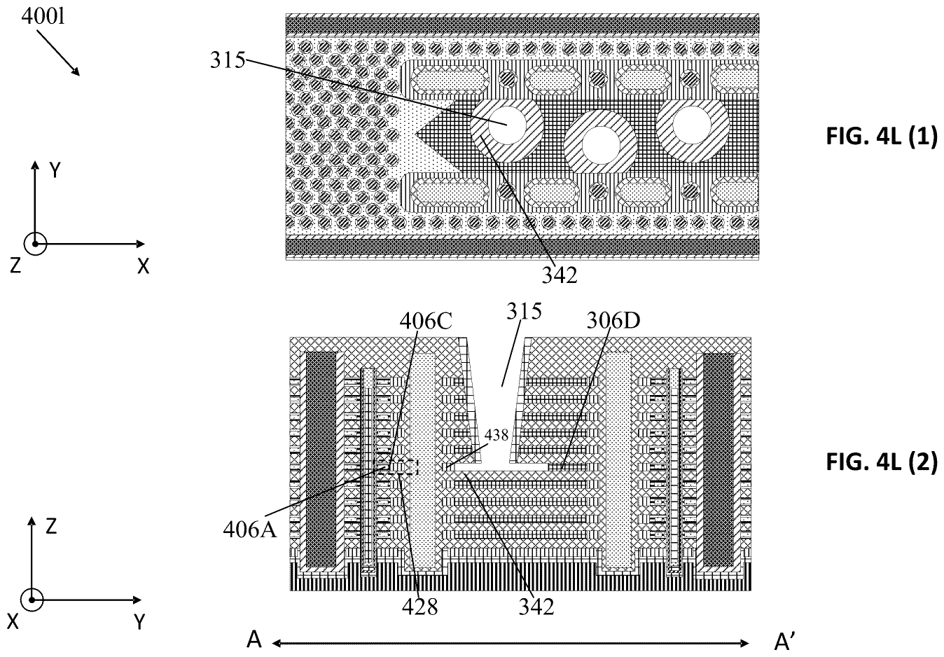

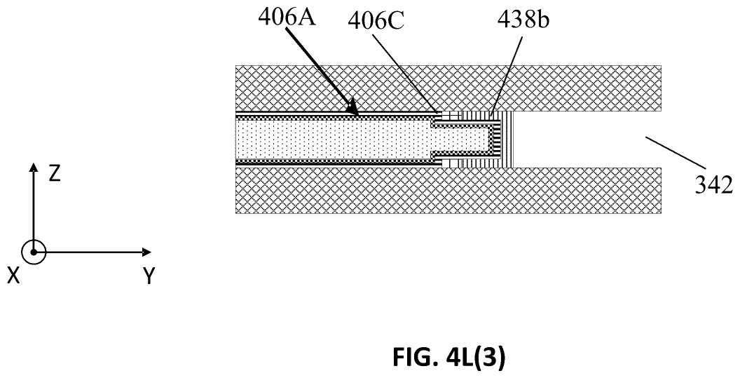

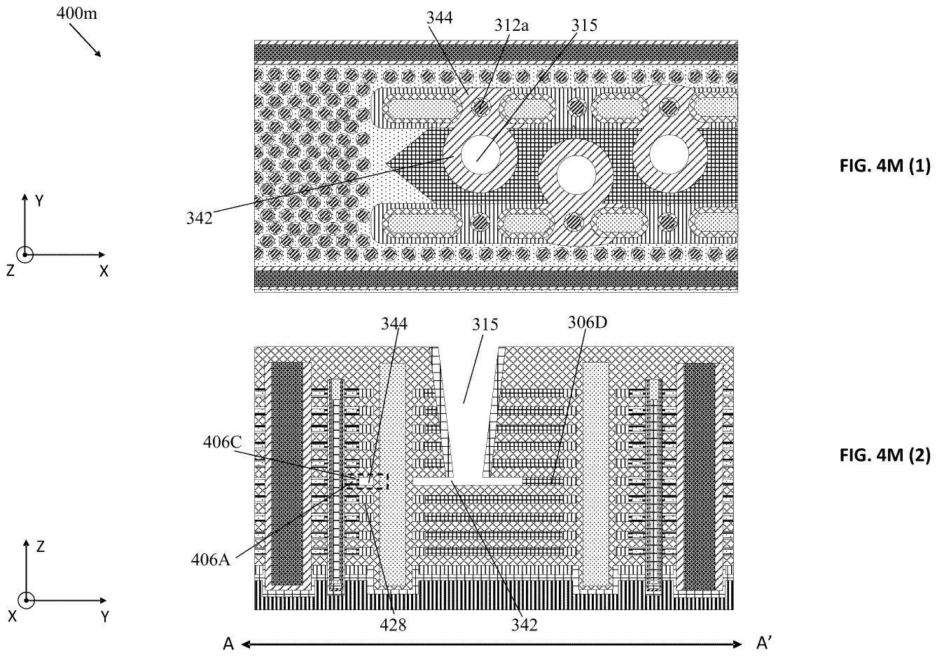

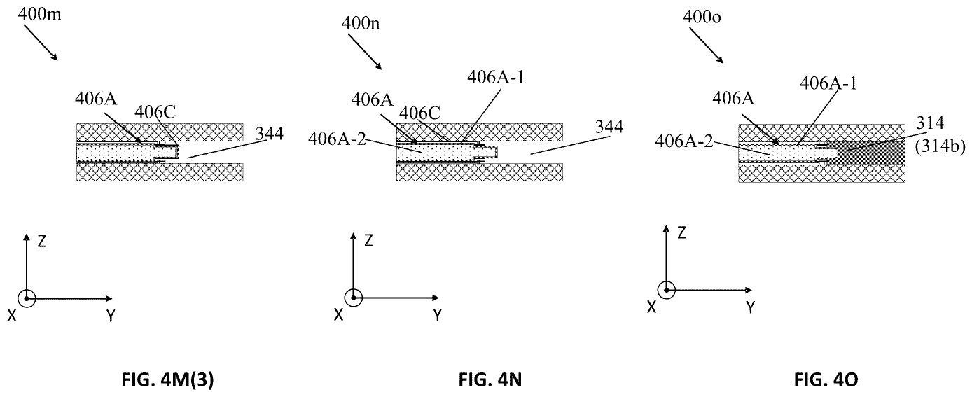

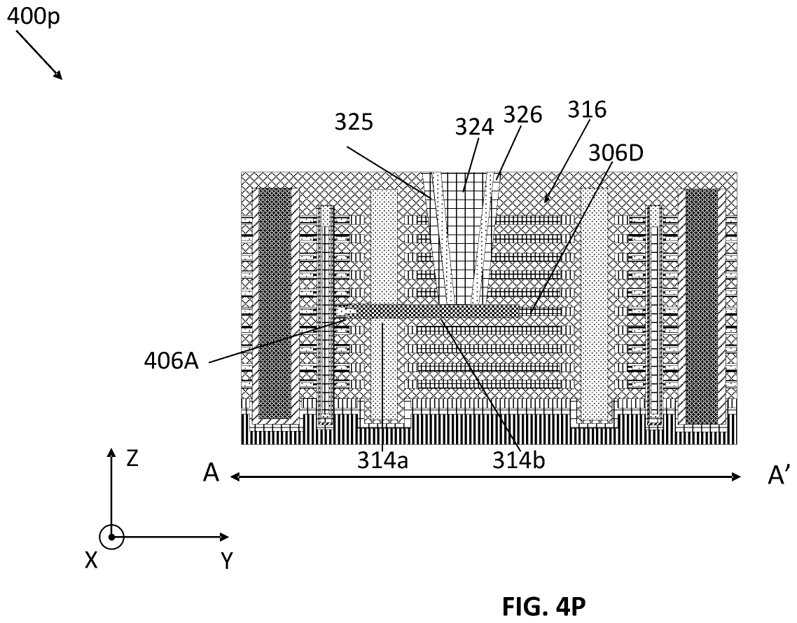

FIG. 4A(1)-4P illustrate an example process of fabricating a semiconductor device, such as the semiconductor device 200 as illustrated in FIGS. 2A-2D. FIG. 4A(1)-4P show top views and cross-sectional views of example semiconductor structures at various stages of the fabrication process.

FIG. 4A(1)-4A(3) illustrate a semiconductor structure 400a. The semiconductor structure 400a can be formed from the semiconductor structure 300e of FIG. 3E(1)-3E(2). The semiconductor structure 400a includes a filler layer 438a and a semiconductor layer 438b in the inner holes 335 and the tunnels 337. FIG. 4A(3) illustrates a cross sectional view of the semiconductor structure 400a along a cut line FF′ of FIG. 4A(1). As shown in FIG. 4A(3), the semiconductor layer 438b can be formed by depositing a semiconductor material (e.g., polysilicon) in the tunnels 337 and the inner holes 335. The semiconductor layer 438b can be in contact with inner surfaces of the tunnels 337 and the inner holes 335. The filler layer 438a can be formed by further depositing a high-K dielectric material in the tunnels 337 and the inner holes 335. The filler layer 438a can fill the remaining space in the tunnels 337 and be surrounded by the semiconductor layer 438b.

FIG. 4B illustrates a semiconductor structure 400b. As shown in FIG. 4B, the filler layer 438a and the semiconductor layer 438b in the semiconductor structure 400b can be recessed (e.g., by one or more etching processes) to expose the isolating layers 306B in the inner holes 335.

FIG. 4C(1)-4C(3) illustrate a semiconductor structure 400c. FIG. 4C(1) illustrates a cross sectional view of the semiconductor structure 400c along the cut line FF′ of FIG. 4A(1). FIG. 4C(2) illustrates a cross sectional view of the semiconductor structure 400c along a cut line GG′ of FIG. 4A(1). FIG. 4C(3) illustrates a top view of the semiconductor structure 400c along a cut line HH′ of FIG. 4C(1). The cut line FF′ extends through one of the inner holes 335, and the cut line GG′ does not extend through the inner holes 335. The semiconductor structure 400c includes one or more isolating walls 420. Each isolating wall 420 includes outer layers 438 and inner structures 436. The outer layers 438 can be similar to, or the same as, the outer layers 238 of FIG. 2B, and the inner structures 436 can be similar to, or the same as, the inner structures 236 of FIG. 2B. Each outer layer 438 can be formed by the filler layer 438a and the semiconductor layer 438b of FIG. 4B. Each inner structure 436 can include a filler layer 436a and a dielectric layer 436b. The dielectric layer 436b is in contact with inner surfaces of the inner holes 335 and can be formed by depositing a dielectric material (e.g., silicon oxide) in the inner holes 335. The filler layer 436a can be formed by further depositing a filler material (e.g., carbon) in the inner holes 335.

As shown in FIG. 4D(1)-4D(2), a semiconductor structure 400d is formed by forming openings in the dielectric layer 307 to expose the filler material in the one or more groups of gate line holes 317 and removing the filler material in the one or more groups of gate line holes 317.

FIG. 4E(1)-4E(2) illustrate a semiconductor structure 400e including one or more gate line spaces 319. Each gate line space 319 can be formed by expanding one group of gate line holes 317 (e.g., by an etching process) and connecting or merging the group of expanded gate line holes 317. In some implementations, protection structures 339b (e.g., poly oxidation) can be formed on bottoms (which can be in contact with the substrate 301) of the one or more gate line spaces 319 to protect the substrate 301.

FIG. 4F(1)-4F(3) illustrate a semiconductor structure 400f including a space 421 formed by an etching process. For example, as shown in FIG. 4F(1)-4F(2), the etching process can include filling an etching solution into the gate line space 319. The space 421 is formed by removing the sacrificial layers 306D of the stack 305 in the array region 302 and portions of the sacrificial layers 306D of the stack 305 in the connection region 304 between each gate line space 319 and adjacent outer layers 438. FIG. 4F(3) illustrate an enlarged cross sectional view of the outer layer 438 along the cut line GG′ of FIG. 4A(1). The semiconductor layer 438b can be exposed in the space 421.

FIG. 4G illustrates a semiconductor structure 400g. The semiconductor structure 400g is formed by removing a portion of the semiconductor layer 438b that is exposed in the space 421 by an etching process. The space 421 is expanded by the etching process.

FIG. 4H illustrates a semiconductor structure 400h. The semiconductor structure 400h is formed by an oxidation process (also referred to as a wet oxidation). A portion of the semiconductor layer 438b can be oxidized by the oxidation process, and the oxidized portion of the semiconductor layer 438b (e.g., silicon oxide) can form a dielectric spacer 440.

FIG. 4I illustrates a semiconductor structure 400i. The semiconductor structure 400i is formed by removing the filler layer 438a (e.g., by using an etching process). The space 421 is further expanded by the etching process.

FIG. 4J(1)-4J(3) illustrate a semiconductor structure 400j including conductive layers 406A and liner layers 406C. The liner layers 406C and the conductive layers 406A can be formed, for example, by depositing (e.g., through the gate line spaces 319) a high-K dielectric material (e.g., Al2O3) and one or more conductive materials (e.g., TiN and W) into the space 321. In some implementations, as shown in FIG. 4J(2), the conductive layers 306A can be connected by excess conductive material deposited on inner surfaces of the gate line spaces 319. Each conductive layer 406A includes a portion between the isolating layers 306B in the array region 302. The conductive layer 406A further includes another portion in the space 321 in the connection region 304 (e.g., a portion between the gate line space 319 and adjacent outer layers 438 along the Y direction in the connection region 304). FIG. 4J(3) illustrate an enlarged cross sectional view (along the cut line GG′ of FIG. 4A(1)) of each conductive layer 406A and an adjacent outer layer 438. The conductive layer 406A includes a layer 406A-1 formed by a first conductive material (e.g., TiN) and a layer 406A-2 formed by a second conductive material (e.g., W). The layer 406A-2 is surrounded by the layer 406A-1. The conductive layer 406A is surrounded by at least one of the liner layers 406C formed by the high-K dielectric material. A portion of the liner layer 406C is between the conductive layer 406A and the dielectric spacer 440 along the Z direction.

FIG. 4K(1)-4K(2) illustrate a semiconductor structure 400k including one or more gate line slit structures 318, a stack 306 of alternating conductive layers 406A and isolating layers 306B, and a stack 308 of alternating dielectric layers 306D and isolating layers 306B. The semiconductor structure 400k is formed by removing the excess conductive material deposited on inner surfaces of the gate line spaces 319, thereby isolating the conductive layers 406A from each other. Each gate line slit structure 318 can include a filling structure 318a and a dielectric layer 318b surrounding the filling structure. The filling structure 318a can include a filler material (e.g., polysilicon), and the dielectric layer 318b can include a dielectric material (e.g., silicon oxide). The gate line slit structures 318 can be formed by depositing the dielectric material and the filler material into the gate line spaces 319.

The stack 306 includes the conductive layers 406A and the liner layers 406C in the array region 302 and the connection region 304. The stack 306 further includes portions of the isolating layers 306B between the conductive layers 406A along the Z direction in the array region 302 and the connection region 304. The stack 308 includes remaining portions of the sacrificial layers or dielectric layers 306D in the connection region 304 and portions of the isolating layers 306B between the sacrificial layers 306D along the Z direction in the connection region 304. The stack 306 can be an example of the stack 106 of the semiconductor device 200 of FIGS. 2A-2B. The stack 308 can be an example of the stack 108 of the semiconductor device 200 of FIGS. 2A-2B.

The semiconductor structure 400k further includes contact holes 315 in the connection region 304. The contact holes 315 can be formed by one or more etching processes. Each contact hole 315 can extend from a top (e.g., a surface farther away from the substrate 301) of the semiconductor structure 400k through the dielectric layer 307 and to one of the sacrificial layers 306D of the stack 308. Each contact hole 315 can extend through at least a part of the stack 308 along the Z direction. For example, as shown in FIG. 4K(2), the contact hole 315 extends into the stack 308 along the Z direction and reaches one of the sacrificial layers 306D of the stack 308. In some implementations, a contact spacer 326 can be deposited on an inner surface of the contact hole 315. The contact spacer 326 can protect the sacrificial layers 306D exposed by the contact hole 315 from being affected by an etching process. In some implementations, each contact hole 315 is aligned with one of the first isolating structures 312a along the Y direction. As shown in FIG. 4K(2), one of the outer layers 438 is in contact with the sacrificial layer 306D and one of the conductive layers 406A along the Y direction. In some implementations, the outer layer 438 is connected to the conductive layer 406A through the liner layer 406C surrounding the conductive layer 406A.

FIG. 4L(1)-4L(3) illustrate a semiconductor structure 400l including a first space 342. The first space 342 can be formed in the sacrificial layer 306D of FIG. 4L(2) by removing (e.g., through an etching process) a portion of the sacrificial layer 306D that is in contact with the contact hole 315 (e.g., along the Z direction) to expose the outer layer 438. FIG. 4L(3) illustrate an enlarged view of a region 428 of FIG. 4L(2). The enlarged view in FIG. 4L(3) is also a cross sectional view taken along the cut line GG′ of FIG. 4A(1). As shown in FIG. 4L(3), the semiconductor layer 438b of the outer layer 438 is exposed in the first space 342.

FIG. 4M(1)-4M(3) illustrate a semiconductor structure 400m including a second space 344. The second space 344 is connected to the first space 342 along the Y direction. The second space 344 can be formed by removing (e.g., through an etching process) the semiconductor layer 438b of the outer layer 438 to expose the liner layer 406C. The first isolating structure 312a can extend through the second space 344 along the Z direction. FIG. 4M(3) illustrate an enlarged view of the region 428 of FIG. 4M(2). The enlarged view in FIG. 4M(3) is also a cross sectional view taken along the cut line GG′ of FIG. 4A(1). As shown in FIG. 4M(3), the semiconductor layer 438b of the outer layer 438 (e.g., as shown in FIG. 4L(3)) has been removed. A portion of the liner layer 406C can be exposed in the second space 344.

FIG. 4N illustrates a semiconductor structure 400n formed by removing the portion of the liner layer 406C exposed in the second space 344 (e.g., as shown in FIG. 4M(3)) through an etching process. The second space 344 can be enlarged by the etching process. As shown in FIG. 4N, a portion of the layer 406A-1 of the conductive layer 406A is exposed in the second space 344.

FIG. 4O illustrates a semiconductor structure 400o including a connecting structure 314. The connecting structure 314 can include a portion 314a (not shown in FIG. 4O) in the first space 342 and a portion 314b in the second space 344. The semiconductor structure 400o can be formed by depositing a conductive material (e.g., TiN or W) into the first space 342 and the second space 344 through the contact hole 315. The portion 314a of the connecting structure 314 can be similar to, or same as the portion 114a of FIG. 1C.

FIG. 4P illustrates a semiconductor structure 400p including contact structures 316. The semiconductor structure 400p is similar to, or same as the semiconductor device 200 of FIGS. 2A-2D. One of the contact structures 316 is connected to the portion 314b of the connecting structure 314 along the Z direction. Each contact structure 316 can include a first layer 324 and a second layer 325 surrounding and being in contact with the first layer 324. The second layer 325 can be surrounded by the contact spacer 326. The first layer 324 and the second layer 325 can extend along the Z direction. The first layer 324 can include a dielectric material (e.g., silicon oxide). The second layer 125 can include a conductive material. The second layer 325 of the contact structure 316 can be formed by depositing the conductive material on an inner surface of the contact hole 315. The first layer 324 of the contact structure 316 can be formed by filling the contact hole 315 with the dielectric material.

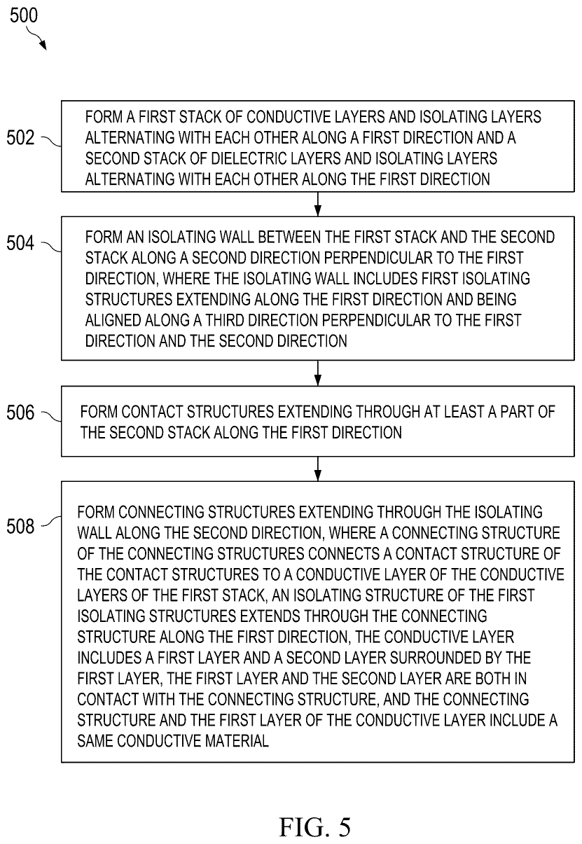

FIG. 5 illustrates a flow chart of an example process 500. The process 500 can be performed to form a semiconductor device (e.g., the semiconductor device 100 illustrated by FIGS. 1A-1F or the semiconductor device 200 illustrated by FIGS. 2A-2D). The process 500 can be described in view of FIG. 3A(1)-3R. The process 500 can include one or more steps of the fabrication process of forming the semiconductor structures in FIG. 3A(1)-3R. It is understood that the operations shown in process 500 are not exhaustive and that other operations can be performed as well before, after, or between any of the illustrated operations. Further, some of the operations may be performed simultaneously, or in a different order than shown in FIG. 5.

At operation 502, a first stack (e.g., the stack 306 of FIG. 3M(1)-3R) of conductive layers (e.g., conductive layers 306A) and isolating layers (e.g., isolating layers 306B) alternating with each other along a first direction (e.g., the Z direction) and a second stack (e.g., the stack 308 of FIG. 3M(1)-3R) of dielectric layers (e.g., sacrificial or dielectric layers 306D) and isolating layers (e.g., isolating layers 306B) alternating with each other along the first direction (e.g., the Z direction) are formed.

At operation 504, an isolating wall (e.g., the isolating wall 320 of FIG. 3H(1)-3H(2)) between the first stack and the second stack along a second direction (e.g., the Y direction) perpendicular to the first direction is formed. The isolating wall includes isolating structures (e.g., the isolating structures 312a of FIG. 3B(1)) extending along the first direction and being aligned along a third direction (e.g., the X direction) perpendicular to the first direction and the second direction.

At operation 506, contact structures (e.g., the contact structures 316 of FIG. 3R) extending through at least a part of the second stack along the first direction are formed.

At operation 508, connecting structures (e.g., the connecting structure 314 of FIGS. 3Q-3R) extending through the isolating wall along the second direction are formed. Forming the connecting structure includes forming a connecting structure of the connecting structures that connects a contact structure (e.g., the contact structure 316 of FIG. 3R) of the contact structures to a conductive layer (e.g., the conductive layer 306A of FIG. 3R) of the conductive layers of the first stack. An isolating structure of the isolating structures extends through the connecting structure (e.g., the portion 314a of the connecting structure 314) along the first direction. The conductive layer includes a first layer (e.g., the layer 306A-1 of FIG. 3Q) and a second layer (e.g., the layer 306A-2 of FIG. 3Q) surrounded by the first layer. The first layer and the second layer of the conductive layer are both in contact with the connecting structure (e.g., the connecting structure 314 of FIG. 3Q). The connecting structure and the first layer of the conductive layer includes a same conductive material (e.g., TiN).

In some implementations, the process 500 further includes forming a stack (e.g., the stack 305 of FIG. 3A(1)-3A(2)) of dielectric layers (e.g., the dielectric layers 306D) and isolating layers (e.g., the isolating layers 306B) alternating with each other along the first direction. The process 500 further includes forming an array of channel holes (e.g., the array of channel holes 309), isolating holes (e.g., the isolating holes 333), dummy channel holes (e.g., the first dummy channel holes 311a), and gate line holes (e.g., the gate line holes 317) extending through the stack of dielectric layers and isolating layers along the first direction by a same etching process. The process 500 further includes forming an array of channel structures (e.g., the channel structures 310 of FIG. 3B(1)-3B(2)) in the array of channel holes and isolating structures (e.g., the first isolating structure 312a) in the dummy channel holes. The process 500 further includes forming inner holes (e.g., the inner holes 335 of FIG. 3D(1)-3D(2)) by expanding and connecting the isolating holes (e.g., the isolating holes 333 of FIG. 3C(1)-3C(2)). The inner holes and the isolating structures alternate with each other along the third direction. The process 500 further includes forming tunnels (e.g., the tunnels 337 of FIG. 3E(1)-3E(2)) between the isolating layers (e.g., the isolating layers 306B) of the stack (e.g., the stack 305) by removing a portion of the dielectric layers (e.g., the dielectric layers 306D) of the stack exposed by the inner holes. The tunnels extend along the third direction (e.g., as shown in FIG. 3E(1)), and the inner holes and the isolating structures extend through the tunnels along the first direction (e.g., as shown in FIG. 3E(2)).

In some implementations, forming the isolating wall includes forming outer layers (e.g., the outer layers 338 of FIG. 3H(1)-3H(2)) of the isolating wall by depositing a first material (e.g., the dielectric material as described with reference to FIG. 3F) on inner surfaces of the tunnels and filling a second material (e.g., the polysilicon as described with reference to FIG. 3F) into the tunnels. Each outer layer includes a first layer (e.g., the dielectric layer 338b of FIG. 3H(1)-3H(2)) including the first material and a second layer (e.g., the filler layer 338a of FIG. 3H(1)-3H(2)) including the second material.

In some implementations, forming the isolating wall further includes forming inner structures (e.g., the inner structures 336 of FIG. 3H(1)-3H(2)) of the isolating wall by removing a portion of the second material exposed by the inner holes (e.g., the inner holes 335) and depositing at least a dielectric material (e.g., as described with reference to FIG. 3H(1)) into the inner holes.

In some implementations, the process 500 further includes forming a gate line space (e.g., the gate line space 319 of FIG. 3J(1)-3J(2)) by expanding the gate line holes. The gate line space includes the expanded gate line holes (e.g., the gate line holes 317) connected with each other along the third direction.

In some implementations, forming the first stack of conductive layers and isolating layers and the second stack of dielectric layers and isolating layers includes removing the dielectric layers (e.g., the sacrificial layers 306D) of the stack (e.g., the stack 305) in an array region (e.g., the array region 302) and the dielectric layers (e.g., the sacrificial layers 306D) of the stack (e.g., the stack 305) in a connection region (e.g., the connection region 304) between the gate line space and the isolating wall by an etching process. The etching process removes a portion of a first layer (e.g., the dielectric layer 338b of FIG. 3K(3)) of an outer layer (e.g., the outer layer 338 of FIG. 3K(3)) of the outer layers of the isolating wall and exposes a portion of a second layer (e.g., the filler layer 338a of FIG. 3K(3)) of the outer layer.

Forming the first stack of conductive layers and isolating layers and the second stack of dielectric layers and isolating layers further includes forming a dielectric spacer (e.g., the dielectric spacer 340 of FIG. 3K(3)) covering the exposed portion of the second layer of the outer layer.

Forming the first stack of conductive layers and isolating layers and the second stack of dielectric layers and isolating layers further includes forming liner layers (e.g., the liner layers 306C) and the conductive layers (e.g., the conductive layers 306A) between the isolating layers of the stack in the array region and the isolating layers of the stack in the connection region between the gate line space and the isolating wall to replace the removed dielectric layers.

In some implementations, forming the conductive layers includes forming the first layer (e.g., the layer 306A-1 of FIG. 3L(3)) of the conductive layer by depositing a first conductive material (e.g., TiN) through the gate line space and forming the second layer (e.g., the layer 306A-2 of FIG. 3L(3)) of the conductive layer by depositing a second conductive material (e.g., W) through the gate line space,

In some implementations, the first stack (e.g., the stack 306 of FIG. 3M(1)-3M(2)) includes the conductive layers and the isolating layers in the array region and the conductive layers and the isolating layers in the connection region between the gate line space and the isolating wall. The second stack (e.g., the stack 308 of FIG. 3M(1)-3M(2)) includes a remaining portion of the dielectric layers of the stack and the isolating layers of the stack in the connection region. The dielectric spacer (e.g., the dielectric spacer 340 of FIG. 3L(3)) and the conductive layer (e.g., the conductive layer 306A of FIG. 3L(3)) are surrounded by a liner layer (e.g., the liner layer 306C of FIG. 3L(3)) of the liner layers along the first direction. A portion of the liner layer is in contact with and between the dielectric spacer and the conductive layer along the second direction.

In some implementations, the process 500 further includes forming a gate line slit structure (e.g., the gate line slit structure 318 of FIG. 3M(1)-3M(2)) by filling the gate line space with a semiconductor material (e.g., polysilicon).

In some implementations, the process 500 further includes forming a contact hole (e.g., the contact hole 315 of FIG. 3M(1)-3M(2)) in the connection region. The contact hole extends into the second stack along the first direction and reaches a dielectric layer (e.g., the dielectric layer 306D of FIG. 3M(2)) of the dielectric layers of the second stack. The contact hole is aligned with the isolating structure (e.g., one of the isolating structures 312a of FIG. 3M(1)) along the second direction. An outer layer (e.g., the outer layer 338 of FIG. 3M(2)) of the outer layers of the isolating wall is in contact with and between the dielectric layer (e.g., the dielectric layer 306D of FIG. 3M(2)) and the conductive layer (e.g., the conductive layer 306A of FIG. 3M(2)) along the second direction.

In some implementations, the process 500 further includes forming a first space (e.g., the first space 342 of FIG. 3N(1)-3N(2)) in the dielectric layer by removing a portion of the dielectric layer between the contact hole and the outer layer to exposes the outer layer.

In some implementations, the process 500 further includes forming a second space (e.g., the second space 344 of FIG. 3O(3)) by removing a portion of the first layer (e.g., the dielectric layer 338b) and the second layer (e.g., the filler layer 338a) of the outer layer to expose the dielectric spacer (e.g., the dielectric spacer 340).

In some implementations, the process 500 further includes expanding the second space (e.g., the space 344 of FIG. 3P) by removing the dielectric spacer (e.g., the dielectric spacer 340) to expose the liner layer (e.g., the liner layer 306C of FIG. 3P).

In some implementations, the process 500 further includes expanding the second space (e.g., the space 344 of FIG. 3P) by removing the liner layer (e.g., the liner layer 306C of FIG. 3P) to expose the conductive layer (e.g., the conductive layer 306A of FIG. 3Q).

In some implementations, forming the connecting structure includes forming the connecting structure by depositing the first conductive material (e.g., TiN) into the first space and the second space through the contact hole (e.g., as described with reference to FIG. 3Q).

In some implementations, forming the contact structure includes forming a first layer (e.g., the layer 325 of FIG. 3R) of the contact structure by depositing the second conductive material (e.g., W) on an inner surface of the contact hole and form a second layer (e.g., the layer 324 of FIG. 3R) of the contact structure by filling the contact hole with a dielectric material (e.g., silicon oxide).

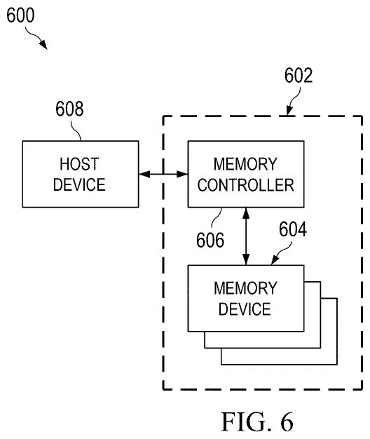

FIG. 6 illustrates a block diagram of an example system 600. The system 600 can have one or more semiconductor devices (e.g., memory devices), according to one or more implementations of the present disclosure. The system 600 can be a mobile phone, a desktop computer, a laptop computer, a tablet, a vehicle computer, a gaming console, a printer, a positioning device, a wearable electronic device, a smart sensor, a virtual reality (VR) device, an argument reality (AR) device, or any other suitable electronic devices having storage. As shown in FIG. 6, the system 600 can include a host device 608 and a memory system 602 having one or more memory devices 604 and a memory controller 606. Host device 608 can include a processor of an electronic device, such as a central processing unit (CPU), or a system-on-chip (SoC), such as an application processor (AP). Host device 608 can be configured to send or receive data to or from the one or more memory devices 604.

A memory device 604 can be any memory device disclosed in the present disclosure, such as a memory device (e.g., a NAND Flash memory) as shown in FIGS. 1A-1F or a memory device as shown in FIGS. 2A-2D. Memory controller 606 (a.k.a., a controller circuit) is coupled to memory device 604 and host device 608. Consistent with implementations of the present disclosure, memory device 604 can include a plurality of conductive interconnections through a cover layer that are in contact with conductive pads in a conductive pad layer, and memory controller 606 can be coupled to memory device 604 through at least one of the plurality of conductive interconnections. Memory controller 606 is configured to control memory device 604. For example, memory controller 606 may be configured to operate a plurality of channel structures via word lines. Memory controller 606 can manage data stored in memory device 604 and communicate with host device 608.

In some implementations, memory controller 606 is designed/configured for operating in a low duty-cycle environment like secure digital (SD) cards, compact Flash (CF) cards, universal serial bus (USB) Flash drives, or other media for use in electronic devices, such as personal computers, digital cameras, mobile phones, etc. In some implementations, memory controller 606 is designed/configured for operating in a high duty cycle environment SSDs or embedded multi-media-cards (eMMCs) used as data storage for mobile devices, such as smartphones, tablets, laptop computers, etc., and enterprise storage arrays. Memory controller 606 can be configured to control operations of memory device 604, such as read, erase, and program (or write) operations. Memory controller 606 can also be configured to manage various functions with respect to the data stored or to be stored in memory device 604 including, but not limited to bad-block management, garbage collection, logical-to-physical address conversion, wear leveling, etc. In some implementations, memory controller 606 is further configured to process error correction codes (ECCs) with respect to the data read from or written to memory device 604. Any other suitable functions may be performed by memory controller 606 as well, for example, formatting memory device 604.

Memory controller 606 can communicate with an external device (e.g., host device 608) according to a particular communication protocol. For example, memory controller 606 may communicate with the external device through at least one of various interface protocols, such as a USB protocol, an MMC protocol, a peripheral component interconnection (PCI) protocol, a PCIexpress (PCI-E) protocol, an advanced technology attachment (ATA) protocol, a serial-ATA protocol, a parallel-ATA protocol, a small computer small interface (SCSI) protocol, an enhanced small disk interface (ESDI) protocol, an integrated drive electronics (IDE) protocol, a Firewire protocol, etc.

Memory controller 606 and one or more memory devices 604 can be integrated into various types of storage devices, for example, be included in the same package, such as a universal Flash storage (UFS) package or an eMMC package. That is, memory system 602 can be implemented and packaged into different types of end electronic products. In one example as shown in FIG. 6, memory controller 606 and a single memory device 604 may be integrated into a memory card 602. Memory card 602 can include a PC card (PCMCIA, personal computer memory card international association), a CF card, a smart media (SM) card, a memory stick, a multimedia card (MMC, RS-MMC, MMCmicro), an SD card (SD, miniSD, microSD, SDHC), a UFS, etc.

Implementations of the subject matter and the actions and operations described in this present disclosure can be implemented in digital electronic circuitry, in tangibly-embodied computer software or firmware, in computer hardware, including the structures disclosed in this present disclosure and their structural equivalents, or in combinations of one or more of them. Implementations of the subject matter described in this present disclosure can be implemented as one or more computer programs, e.g., one or more modules of computer program instructions, encoded on a computer program carrier, for execution by, or to control the operation of, data processing apparatus. The carrier may be a tangible non-transitory computer storage medium. Alternatively, or in addition, the carrier may be an artificially-generated propagated signal, e.g., a machine-generated electrical, optical, or electromagnetic signal, that is generated to encode information for transmission to suitable receiver apparatus for execution by a data processing apparatus. The computer storage medium can be or be part of a machine-readable storage device, a machine-readable storage substrate, a random or serial access memory device, or a combination of one or more of them. A computer storage medium is not a propagated signal.

It is noted that references in the present disclosure to “one embodiment,” “an embodiment,” “an example embodiment,” “some implementations,” “some implementations,” etc., indicate that the embodiment described can include a particular feature, structure, or characteristic, but every embodiment can not necessarily include the particular feature, structure, or characteristic. Moreover, such phrases do not necessarily refer to the same embodiment. Further, when a particular feature, structure or characteristic is described in connection with an embodiment, it would be within the knowledge of a person skilled in the pertinent art to affect such feature, structure or characteristic in connection with other implementations whether or not explicitly described.

In general, terminology can be understood at least in part from usage in context. For example, the term “one or more” as used herein, depending at least in part upon context, can be used to describe any feature, structure, or characteristic in a singular sense or can be used to describe combinations of features, structures or characteristics in a plural sense. Similarly, terms, such as “a,” “an,” or “the,” again, can be understood to convey a singular usage or to convey a plural usage, depending at least in part upon context. In addition, the term “based on” can be understood as not necessarily intended to convey an exclusive set of factors and may, instead, allow for existence of additional factors not necessarily expressly described, again, depending at least in part on context.

It should be readily understood that the meaning of “on,” “above,” and “over” in the present disclosure should be interpreted in the broadest manner such that “on” not only means “directly on” something, but also includes the meaning of “on” something with an intermediate feature or a layer therebetween. Moreover, “above” or “over” not only means “above” or “over” something, but can also include the meaning it is “above” or “over” something with no intermediate feature or layer therebetween (i.e., directly on something).

Further, spatially relative terms, such as “beneath,” “below,” “lower,” “above,” “upper,” and the like, can be used herein for ease of description to describe one element or feature's relationship to another element(s) or feature(s) as illustrated in the figures. The spatially relative terms are intended to encompass different orientations of the device in use or process step in addition to the orientation depicted in the figures. The apparatus can be otherwise oriented (rotated 90 degrees or at other orientations) and the spatially relative descriptors used herein can likewise be interpreted accordingly.

As used herein, the term “substrate” refers to a material onto which subsequent material layers are added. The substrate includes a “top” surface and a “bottom” surface. The top surface of the substrate is typically where a semiconductor device is formed, and therefore the semiconductor device is formed at a top side of the substrate unless stated otherwise. The bottom surface is opposite to the top surface and therefore a bottom side of the substrate is opposite to the top side of the substrate. The substrate itself can be patterned. Materials added on top of the substrate can be patterned or can remain unpatterned. Furthermore, the substrate can include a wide array of semiconductor materials, such as silicon, germanium, gallium arsenide, indium phosphide, etc. Alternatively, the substrate can be made from an electrically noN+ conductive material, such as a glass, a plastic, or a sapphire wafer.

As used herein, the term “layer” refers to a material portion including a region with a thickness. A layer has a top side and a bottom side where the bottom side of the layer is relatively close to the substrate and the top side is relatively away from the substrate. A layer can extend over the entirety of an underlying or overlying structure, or can have an extent less than the extent of an underlying or overlying structure. Further, a layer can be a region of a homogeneous or inhomogeneous continuous structure that has a thickness less than the thickness of the continuous structure. For example, a layer can be located between any set of horizontal planes between, or at, a top surface and a bottom surface of the continuous structure. A layer can extend horizontally, vertically, and/or along a tapered surface. A substrate can be a layer, can include one or more layers therein, and/or can have one or more layer thereupon, thereabove, and/or therebelow. A layer can include multiple layers. For example, an interconnect layer can include one or more conductive and contact layers (in which contacts, interconnect lines, and/or vertical interconnect accesses (VIAs) are formed) and one or more dielectric layers.

As used herein, the term “nominal/nominally” refers to a desired, or target, value of a characteristic or parameter for a component or a process step, set during the design phase of a product or a process, together with a range of values above and/or below the desired value. As used herein, the range of values can be due to slight variations in manufacturing processes or tolerances. As used herein, the term “about” indicates the value of a given quantity that can vary based on a particular technology node associated with the subject semiconductor device. Based on the particular technology node, the term “about” can indicate a value of a given quantity that varies within, for example, 10-30% of the value (e.g., .+−.10%, .+−.20%, or .+−.30% of the value).

In the present disclosure, the term “horizontal/horizontally/lateral/laterally” means nominally parallel to a lateral surface of a substrate, and the term “vertical” or “vertically” means nominally perpendicular to the lateral surface of a substrate.

As used herein, the term “3D memory” refers to a three-dimensional (3D) semiconductor device with vertically oriented strings of memory cell transistors (referred to herein as “memory strings,” such as NAND strings) on a laterally-oriented substrate so that the memory strings extend in the vertical direction with respect to the substrate.

The present disclosure provides many different implementations, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include implementations in which the first and second features may be in direct contact, and may also include implementations in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various implementations and/or configurations discussed.

The foregoing description of the specific implementations can be readily modified and/or adapted for various applications. Therefore, such adaptations and modifications are intended to be within the meaning and range of equivalents of the disclosed implementations, based on the teaching and guidance presented herein.

While the present disclosure contains many specific implementation details, these should not be construed as limitations on the scope of what is being claimed, which is defined by the claims themselves, but rather as descriptions of features that may be specific to particular implementations of particular inventions. Certain features that are described in this present disclosure in the context of separate implementations can also be implemented in combination in a single embodiment. Conversely, various features that are described in the context of a single embodiment can also be implemented in multiple implementations separately or in any suitable sub-combination. Moreover, although features may be described above as acting in certain combinations and even initially be claimed as such, one or more features from a claimed combination can in some cases be excised from the combination, and the claim may be directed to a sub-combination or variation of a sub-combination.

Similarly, while operations are depicted in the drawings and recited in the claims in a particular order, this should not be understood as requiring that such operations be performed in the particular order shown or in sequential order, or that all illustrated operations be performed, to achieve desirable results. In certain circumstances, multitasking and parallel processing may be advantageous. Moreover, the separation of various system modules and components in the implementations described above should not be understood as requiring such separation in all implementations, and it should be understood that the described program components and systems can generally be integrated together in a single software product or packaged into multiple software products.

Particular implementations of the subject matter have been described. Other implementations also are within the scope of the following claims. For example, the actions recited in the claims can be performed in a different order and still achieve desirable results. As one example, the processes depicted in the accompanying figures do not necessarily require the particular order shown, or sequential order, to achieve desirable results. In some cases, multitasking and parallel processing may be advantageous.

The breadth and scope of the present disclosure should not be limited by any of the above-described exemplary implementations, but should be defined only in accordance with the following claims and their equivalents.

What is claimed is:

1. A semiconductor device, comprising:
a first stack of conductive layers and isolating layers alternating with each other along a first direction;
a second stack of dielectric layers and isolating layers alternating with each other along the first direction;
an isolating wall between the first stack and the second stack along a second direction perpendicular to the first direction, wherein the isolating wall comprises isolating structures extending along the first direction and being aligned along a third direction perpendicular to the first direction and the second direction;
contact structures extending through at least a part of the second stack along the first direction; and
connecting structures extending through the isolating wall along the second direction, wherein a connecting structure of the connecting structures connects a contact structure of the contact structures to a conductive layer of the conductive layers of the first stack, an isolating structure of the isolating structures extends through the connecting structure along the first direction, the conductive layer comprises a first layer and a second layer surrounded by the first layer, the first layer and the second layer of the conductive layer are both in contact with the connecting structure, and the connecting structure and the first layer of the conductive layer comprise a same conductive material.

2. The semiconductor device of claim 1, wherein the connecting structure is connected to an end of the conductive layer along the second direction, and a size of the connecting structure along the first direction is different from a size of the end of the conductive layer along the first direction.

3. The semiconductor device of claim 2, wherein an end of the connecting structure is connected to the end of the conductive layer along the second direction, the end of the connecting structure is in contact with and is surrounded by a first liner layer and a second liner layer disposed at two opposite sides of the end of the connecting structure along the first direction, the end of the conductive layer is in contact with and between the first liner layer and the second liner layer along the first direction, and a size of the end of the connecting structure along the first direction is larger than the size of the end of the conductive layer along the first direction.

4. The semiconductor device of claim 2, wherein a first portion of the end of the conductive layer extends into the connecting structure along the second direction, a second portion of the end of the conductive layer is in contact with and between a first liner layer and a second liner layer disposed at two opposite sides of the end of the conductive layer along the first direction, and the size of the connecting structure along the first direction is larger than a size of the second portion of the end of the conductive layer along the first direction.

5. The semiconductor device of claim 4, wherein a body of the conductive layer is connected to the end of the conductive layer along the second direction, the body of the conductive layer is in contact with and between the first liner layer and the second liner layer along the first direction, and the size of the second portion of the end of the conductive layer along the first direction is smaller than a size of the body of the conductive layer along the first direction.

6. The semiconductor device of claim 1, wherein the isolating wall further comprises:
inner structures extending along the first direction and being spaced along the third direction, wherein the inner structures and the isolating structures alternate with each other along the third direction; and
outer layers extending along the third direction and being spaced along the first direction, wherein the inner structures and the isolating structures extend through the outer layers along the first direction, wherein the inner structures are surrounded by the outer layers.

7. The semiconductor device of claim 6, wherein an outer layer of the outer layers comprises a first layer and a second layer, and the first layer of the outer layer and the second layer of the outer layer comprises different materials.

8. The semiconductor device of claim 6, wherein an inner structure of the inner structures comprises a dielectric layer and a filler material surrounded by the dielectric layer.

9. The semiconductor device of claim 1, wherein along the third direction, a first size of the connecting structure at a first location is smaller than a second size of the connecting structure at a second location, the first location being closer to a center of the isolating structure than the second location along the second direction.

10. The semiconductor device of claim 1, wherein the semiconductor device comprises an array region and a connection region adjacent to the array region in the second direction, a first portion of the first stack is in the array region, a second portion of the first stack is in the connection region, the second stack is in the connection region, and the semiconductor device comprises an array of channel structures in the array region.

11. The semiconductor device of claim 1, comprising a first semiconductor structure and a second semiconductor structure bonded together, wherein the first semiconductor structure comprises the first stack, the second stack, the isolating wall, the contact structures, and the connecting structure, and wherein the second semiconductor structure comprises a peripheral circuit coupled to the first semiconductor structure and configured to control the semiconductor device.

12. A semiconductor device, comprising:
a first stack of conductive layers and isolating layers alternating with each other along a first direction;
a second stack of dielectric layers and isolating layers alternating with each other along the first direction;
an isolating wall between the first stack and the second stack along a second direction perpendicular to the first direction, wherein the isolating wall comprises isolating structures extending along the first direction and being spaced along a third direction perpendicular to the first direction and the second direction;
contact structures extending through at least a part of the second stack along the first direction; and
connecting structures extending through the isolating wall along the second direction, wherein a connecting structure of the connecting structures connects a contact structure of the contact structures to an end of a conductive layer of the conductive layers of the first stack, an isolating structure of the isolating structures extends through the connecting structure along the first direction, and a size of the connecting structure along the first direction is different from a size of the end of the conductive layer along the first direction.

13. The semiconductor device of claim 12, wherein the connecting structure comprises a first layer, the conductive layer comprises a first layer and a second layer both in contact with the first layer of the connecting structure, and the first layer of the connecting structure and the first layer of the conductive layer comprise a same conductive material.

14. The semiconductor device of claim 12, wherein an end of the connecting structure is connected to the end of the conductive layer along the second direction, the end of the connecting structure is in contact with and between a first liner layer and a second liner layer disposed at two opposite sides of the end of the connecting structure along the first direction, the end of the conductive layer is contact with and between the first liner layer and the second liner layer along the first direction, and a size of the end of the connecting structure along the first direction is larger than the size of the end of the conductive layer along the first direction.

15. A method of forming a semiconductor device, comprising:
forming a first stack of conductive layers and isolating layers alternating with each other along a first direction and a second stack of dielectric layers and isolating layers alternating with each other along the first direction;
forming an isolating wall between the first stack and the second stack along a second direction perpendicular to the first direction, wherein the isolating wall comprises isolating structures extending along the first direction and being aligned along a third direction perpendicular to the first direction and the second direction;
forming contact structures extending through at least a part of the second stack along the first direction; and
forming connecting structures extending through the isolating wall along the second direction, wherein forming the connecting structure comprises:
forming a connecting structure of the connecting structures that connects a contact structure of the contact structures to a conductive layer of the conductive layers of the first stack, an isolating structure of the isolating structures extends through the connecting structure along the first direction, the conductive layer comprises a first layer and a second layer surrounded by the first layer, the first layer and the second layer of the conductive layer are both in contact with the connecting structure, and the connecting structure and the first layer of the conductive layer comprise a same conductive material.

16. The method of claim 15, further comprising:
forming a stack of dielectric layers and isolating layers alternating with each other along the first direction;
forming an array of channel holes, isolating holes, dummy channel holes, and gate line holes extending through the stack of dielectric layers and isolating layers along the first direction by a same etching process;
forming an array of channel structures in the array of channel holes, and isolating structures in the dummy channel holes;
forming inner holes by expanding and connecting the isolating holes, wherein the inner holes and the isolating structures alternate with each other along the third direction; and
forming tunnels between the isolating layers of the stack by removing a portion of the dielectric layers of the stack exposed by the inner holes, wherein the tunnels extend along the third direction, and the inner holes and the isolating structures extend through the tunnels along the first direction.

17. The method of claim 16, wherein forming the isolating wall comprises:
forming outer layers of the isolating wall by depositing a first material on inner surfaces of the tunnels and filling a second material into the tunnels, wherein each outer layer comprises a first layer comprising the first material and a second layer comprising the second material; and
forming inner structures of the isolating wall by removing a portion of the second material exposed by the inner holes and depositing at least a dielectric material into the inner holes,
and the method further comprises:
forming a gate line space by expanding the gate line holes, wherein the gate line space comprises the expanded gate line holes connected with each other along the third direction.

18. The method of claim 17, wherein forming the first stack of conductive layers and isolating layers and the second stack of dielectric layers and isolating layers comprises:
removing the dielectric layers of the stack in an array region and the dielectric layers of the stack in a connection region between the gate line space and the isolating wall by an etching process, wherein the etching process removes a portion of a first layer of an outer layer of the outer layers of the isolating wall and exposes a portion of a second layer of the outer layer;
forming a dielectric spacer covering the exposed portion of the second layer of the outer layer; and
forming liner layers and the conductive layers between the isolating layers of the stack in the array region and the isolating layers of the stack in the connection region between the gate line space and the isolating wall to replace the removed dielectric layers,
wherein forming the conductive layers comprises forming the first layer of the conductive layer by depositing a first conductive material through the gate line space and forming the second layer of the conductive layer by depositing a second conductive material through the gate line space,
and wherein the first stack comprises the conductive layers and the isolating layers in the array region and the conductive layers and the isolating layers in the connection region between the gate line space and the isolating wall, the second stack comprises a remaining portion of the dielectric layers of the stack and the isolating layers of the stack in the connection region, the dielectric spacer and the conductive layer are surrounded by one of the liner layers along the first direction, and a portion of the liner layer is in contact with and between the dielectric spacer and the conductive layer along the second direction.

19. The method of claim 18, further comprising:
forming a gate line slit structure by filling the gate line space with a semiconductor material;
forming a contact hole in the connection region, wherein the contact hole extends into the second stack along the first direction and reaches a dielectric layer of the dielectric layers of the second stack, the contact hole is aligned with the isolating structure along the second direction, an outer layer of the outer layers of the isolating wall is in contact with and between the dielectric layer and the conductive layer along the second direction;
forming a first space in the dielectric layer by removing a portion of the dielectric layer between the contact hole and the outer layer to exposes the outer layer;
forming a second space by removing a portion of the first layer and the second layer of the outer layer to expose the dielectric spacer;
expanding the second space by removing the dielectric spacer to expose the liner layer; and
expanding the second space by removing the liner layer to expose the conductive layer.

20. The method of claim 19, wherein forming the connecting structure comprises forming the connecting structure by depositing the first conductive material into the first space and the second space through the contact hole, and wherein forming the contact structure comprises:
forming a first layer of the contact structure by depositing the second conductive material on an inner surface of the contact hole; and
form a second layer of the contact structure by filling the contact hole with a dielectric material.
